(19) United States
(12) Patent Application Publication
(10) Pub. No.: US 2024/0363800 A1
(43) Pub. Date: Oct. 31, 2024

(54) TRANSFER PRINTING MICRO-COMPONENTS FROM CARRIER SUBSTRATES

(71) Applicant: X Display Company Technology Limited, Dublin (IE)

(72) Inventors: Carl Ray Prevatte, Raleigh, NC (US); Matthew Alexander Meitl, Durham, NC (US); Andrew Tyler Pearson, Durham, NC (US); Christopher Andrew Bower, Raleigh, NC (US); Ronald S. Cok, Rochester, NY (US)

(21) Appl. No.: 18/640,131

(22) Filed: Apr. 19, 2024

Related U.S. Application Data
(60) Provisional application No. 63/462,927, filed on Apr. 28, 2023.

(51) Int. Cl. H01L 33/20; H01L 25/075; H01L 33/44

(52) U.S. Cl. CPC H01L 33/20; H01L 25/0753; H01L 33/44; H01L 2933/0025

(57) ABSTRACT

A micro-component substrate structure includes a carrier substrate having a corrugated surface and a micro-component having a bottom surface disposed on the corrugated surface. Only a portion of the micro-component bottom surface is in direct contact with the corrugated surface. The micro-component can be removed from the corrugated surface using micro-transfer printing without a tether or anchor structure in the carrier substrate using a stamp with stamp posts. The corrugated surface can be coated with a film. The stamp posts and film can be PDMS and can have different adhesive qualities or areas in contact with the micro-component. The film can be processed to modify its adhesive qualities.

### CROSS-REFERENCE TO RELATED APPLICATION

The present application claims the benefit of U.S. Provisional Patent Application No. 63/462,927, filed on Apr. 28, 2023, the disclosure of which is hereby incorporated by reference herein in its entirety.

### FIELD OF THE DISCLOSURE

The present disclosure relates to structures and methods for transfer printing micro-components from a carrier substrate non-native to the micro-components.

### BACKGROUND

Integrated circuits (ICs) are widely used in electronic devices. Integrated circuits are typically formed on a semiconductor wafer using photolithographic processes and then packaged, for example in a ceramic or plastic package, with pins or bumps on the package providing externally accessible electrical connections to the integrated circuit. An unpackaged integrated circuit is often referred to as a die. Each die typically has electrical contact pads on the top of the integrated circuit that are electrically connected to electronic circuits in the integrated circuit. The die is placed in a cavity in the package, the electrical contact pads are wire-bonded and electrically connected to the package pins or bumps, and the package is sealed. Frequently, multiple identical devices are formed in the semiconductor wafer and the wafer is cut (for example by scribing-and-breaking or by sawing the wafer) into separate integrated circuit dies that are each individually packaged. The packages are then mounted and electrically connected on a printed-circuit board to make an electronic system.

In an alternative flip-chip approach, small spheres of solder (solder bumps) are deposited on the integrated-circuit contact pads and the integrated circuit is flipped over so that the top side of the die with the solder bumps is located adjacent to the package or other destination substrate. This approach is particularly useful for packages such as pin-grid array packages because they can require less space than a wire-bond process. However, flipping the integrated circuit over can be difficult for very small integrated circuits having dimensions in the range of microns. Such small integrated circuit dies are not easily handled without loss or damage using conventional pick-and-place or vacuum tools.

In some applications, the bare integrated-circuit dies are not separately packaged but are placed on a destination substrate and electrically connected on the destination substrate, for example using photolithographic or printed-circuit board methods, to form an electronic system. However, as with flip-chip handling, this can be difficult to accomplish when the integrated-circuit dies are small. Nonetheless, an efficient method of transferring bare dies from a relatively small and expensive source substrate (e.g., crystalline semiconductor) to a relatively large and inexpensive destination substrate (e.g., amorphous glass or plastic) is very desirable, since the integrated circuits can provide much higher data processing efficiency than thin-film semiconductor structures formed on large substrates.

One approach to handling and placing small integrated circuits (chiplets) uses a handle substrate adhered to the side of the integrated circuits opposite the wafer (the top side), the wafer is removed, for example by grinding, the integrated circuits are adhered to the destination substrate, and the handle substrate is removed. In yet another variation, the handle substrate is the destination substrate and is not removed. In this case, the integrated circuit is flipped over so that the top side of the integrated circuit is adhered to the destination substrate.

In another method, epitaxial semiconductor layers are formed on a growth substrate, for example a sapphire substrate. A handle substrate is adhered to the top side of the semiconductor layers opposite the growth substrate, and the growth substrate is removed. The flipped semiconductor layers are then processed to form the integrated circuits. For example, U.S. Pat. No. 6,825,559 describes such a method to make light emitting diodes.

Groups of small integrated circuits (chiplets) can be individually handled and placed using micro-transfer printing, for example as described in U.S. Pat. Nos. 8,722,458, 7,622,367 and 8,506,867, each of which is hereby incorporated by reference in its entirety. In exemplary embodiments of these methods, an integrated circuit is formed on a source wafer, for example a semiconductor wafer, and undercut by etching a gap between a bottom side of the integrated circuit and the wafer. A stamp contacts a top side of the integrated circuit to adhere the integrated circuit to the stamp, the stamp and integrated circuit are transported to a destination substrate, for example a glass or plastic substrate, the integrated circuit is contacted and adhered to the destination substrate, and the stamp removed to “print” the integrated circuit from the source wafer to the destination substrate. Multiple integrated circuits can be “printed” in a common step with a single stamp. The integrated circuits can then be electrically connected using conventional photolithographic or printed-circuit board methods, or both. This technique has the advantage of locating many (e.g., tens or hundreds of thousands of) small integrated-circuit devices on a destination substrate in a single print step. For example, U.S. Pat. No. 8,722,458 teaches transferring light-emitting, light-sensing, or light-collecting semiconductor elements from a wafer substrate to a destination substrate using a patterned elastomer stamp whose spatial pattern matches the location of the semiconductor elements on the wafer substrate.

The cost and throughput of a micro-transfer printing assembly process depends in part on the number of integrated circuits that can be transferred in each printing step and the number of printing steps necessary to complete the assembly. Assembly cost can be reduced, and throughput can be increased by assembling micro-components from respective source substrates into groups on an intermediate substrate that are then assembled, as a group, onto a destination substrate. The spatial density of the micro-components on the intermediate substrate is less than or equal to the spatial density of the micro-components on the respective source substrate and greater than a spatial density of the groups on the destination substrate. This efficient micro-assembly method is discussed at length in U.S. Pat. No. 10,217,730, whose contents are hereby incorporated by reference.

There is a need, therefore, for wafer and micro-component structures and methods that enable efficient and cost-effective micro-component assembly into an integrated system.

### SUMMARY

According to embodiments of the present disclosure, inter alia, a micro-component substrate structure comprising a carrier substrate having a corrugated surface and a micro-component having a bottom surface disposed on (e.g., directly on and in physical contact with) the corrugated surface. The micro-component can have a lateral dimension no greater than two hundred, one hundred, fifty, twenty, ten, five, two, or one micron and a thickness no greater than one hundred, fifty, twenty, ten, five, two, or one micron. The micro-component can be constructed using photolithographic processes and can be an integrated circuit or assembly of integrated circuits. The corrugated surface can comprise an array of rounded, pyramidal, cylindrical, rectangular, or tetrahedral corrugations.

In embodiments of the present disclosure, only a portion (e.g., no more than 25%, no more than 20%, or no more than 10%) of an outermost surface of each of one or more of the corrugations is in contact with the micro-component or a plurality of the corrugations is in contact with the micro-component. The micro-component (e.g., a bottom surface of the micro-component adjacent to the corrugated surface) can contact some but not all of the corrugations and contact only a portion of each corrugation. The corrugated surface can contact multiple micro-components and multiple micro-components can be disposed on and in contact with the corrugated surface. The film can comprise the corrugated surface.

In some embodiments, the film comprises corrugations defining the corrugated surface. In some embodiments, the bulk layer comprises corrugations and the film is disposed on the corrugations. In some embodiments, the bulk layer is a rigid layer (e.g., comprising an oxide, glass, or silicon). In some embodiments, the corrugations are made of a rigid material (e.g., comprising an oxide, glass, or silicon).

The carrier substrate can comprise a bulk layer (e.g., a bulk substrate) having a structured surface coated with a film. The bulk layer can comprise a bulk material. The film can comprise a film material different from the bulk material. In some embodiments, the film material is PDMS. In some embodiments, the bulk material is silicon. The film can have a thickness of no greater than ten microns, five microns, two microns, one micron, one half of a micron, one fifth of a micron, or one tenth of a micron. The corrugated surface can have corrugations having a height of no greater than one hundred microns, fifty microns, twenty microns, ten microns, five microns, two microns, or one micron.

In some embodiments, a surface material of the corrugated surface (e.g., a film comprising the corrugated surface) is or has been processed to reduce adhesion between the micro-component and the corrugated surface.

In embodiments of the present disclosure, a method of transfer printing a micro-component comprises providing a micro-component substrate structure, providing a transfer device (e.g., a stamp), contacting the transfer device to the micro-component, and removing the micro-component from the corrugated surface with the transfer device. The micro-component can be transfer printed onto a target substrate with the transfer device (or a different transfer device or different stamp). In some embodiments, an area of the micro-component in direct contact with the corrugated surface is less than an area of the micro-component in contact with the transfer device when removing the micro-component from the corrugated surface with the transfer device. In some embodiments, the micro-component is a first micro-component disposed on a first region of the carrier substrate and methods of the present disclosure comprise disposing a second micro-component on a second region of the carrier substrate with the transfer device on and in direct contact with the second region of the carrier substrate at least partially overlapping the first region after the first micro-component is removed from the carrier substrate with the transfer device.

In embodiments of the present disclosure, a method of transfer printing a micro-component comprises providing a carrier substrate, providing a micro-component adhered to the carrier substrate with a carrier-substrate adhesion, providing a stamp, contacting the stamp to the micro-component with a stamp adhesion to the micro-component greater than the carrier-substrate adhesion, and removing the micro-component from the carrier substrate. In some embodiments, the carrier substrate has a corrugated surface. In some embodiments a material or composition of the stamp in contact with the micro-component is different from a material or composition of the carrier substrate in contact with the micro-component. In embodiments, the composition can be constituent materials combined in a desired ratio and different materials or compositions can comprise a material with the same constituent materials combined in different ratios, for example, PDMS with different ratios of curing agents, diluents or rinsing agents, and polydimethylsiloxane. For example, the different materials can be different due to having different compositions of one or more same constituents (e.g., different compositions of PDMS)]. Thus, in some embodiments, the PDMS of a stamp has a stamp ratio of constituent materials, the PDMS of a carrier substrate has a substrate ratio of the same constituent materials, and the stamp ratio is different from the substrate ratio.

In embodiments, the carrier substrate comprises or is coated with a layer (e.g., a film) of PDMS that provides the carrier-substrate adhesion to the micro-component, the layer of PDMS of the carrier substrate having a substrate composition and the stamp comprises or is coated with a layer of PDMS having a transfer-device (e.g., stamp) composition. In some embodiments, the transfer-device and substrate compositions are the same. In some embodiments, the transfer-device and substrate compositions are different. In some embodiments, the stamp and substrate have substantially equal tackiness or stickiness (are substantially equally adhesive), e.g., over an equivalent or substantially same area to a given material, e.g., a material of the bottom side of the micro-component in contact with the stamp or corrugated surface. In some embodiments, the stamp and substrate have different tackiness or stickiness (are differently adhesive), e.g., over an equivalent or substantially same area to a given material, e.g., a material of the bottom side of the micro-component in contact with the stamp or corrugated surface.

In some embodiments, the transfer device is a stamp and an area of the micro-component in direct contact with the corrugated surface is less than an area of the micro-component in contact with the stamp when removing the micro-component from the corrugated surface of the carrier substrate with the stamp.

In embodiments, methods of the present disclosure can be iteratively repeated. For example, the micro-component can be a first micro-component and methods can comprise disposing a second micro-component in direct contact with the carrier substrate (e.g., in a second region at least partially overlapping a first region where the first micro-component had been disposed on the carrier substrate) after the first micro-component is removed from the carrier substrate.

According to embodiments of the present disclosure, a method of transfer printing a micro-component comprises providing a carrier substrate, providing a micro-component adhered to the carrier substrate, providing a transfer device (e.g., a stamp) having a transfer device adhesion to the micro-component greater than a carrier-substrate adhesion to the micro-component, contacting the transfer device to the micro-component, and removing the micro-component from the carrier substrate with the transfer device. In embodiments, the carrier substrate has a corrugated surface. In embodiments a material or composition of the transfer device in contact with the micro-component is different from a material or composition of the carrier substrate in contact with the micro-component. In some embodiments, the carrier substrate has a corrugated surface and a material or composition of the transfer device in contact with the micro-component is different from a material or composition of the carrier substrate in contact with the micro-component.

In some embodiments, the carrier substrate comprises or is coated with a layer of PDMS having a substrate composition and the stamp comprises or is coated with a layer of PDMS having a stamp composition different from the substrate composition. In some embodiments, the layer of PDMS on the stamp is more adhesive than the layer of PDMS on the carrier substrate over an equivalent area to an equivalent material and the PDMS of the stamp has a stamp ratio of constituent materials, the PDMS of the carrier substrate has a substrate ratio of the same constituent materials, and the stamp ratio is different from the substrate ratio. An area of the stamp in contact with the micro-component can be greater than an area of the micro-component in contact with the carrier-substrate surface.

In some embodiments, the micro-component is a first micro-component and comprising disposing a second micro-component in direct contact with the carrier substrate after the first micro-component is removed from the carrier substrate.

Some embodiments comprise providing a target substrate and contacting the micro-component to a surface of the target substrate with the stamp wherein the surface of the target substrate has an adhesion greater than the adhesion between the stamp and the micro-component.

Some methods of the present disclosure comprise providing a carrier substrate coated with a temperature-dependent adhesive at a first temperature (or heating or cooling the carrier substrate to the first temperature), contacting a micro-component to the temperature-dependent adhesive on the carrier substrate at the first temperature, changing the temperature of the temperature-dependent adhesive on the carrier substrate to a second temperature different from the first temperature to weaken the adhesion of the temperature-dependent adhesive to the micro-component, and removing the micro-component from the temperature-dependent adhesive on the carrier substrate at the second temperature. The micro-component can be a first micro-component and methods of the present disclosure comprise disposing a second micro-component in direct contact with the carrier-substrate surface after the first micro-component is removed from the carrier-substrate surface. The first and second micro-components can be disposed on the same, similar, or overlapping regions (e.g., areas or portions) of the carrier substrate.

In some methods of the present disclosure, providing the temperature-dependent adhesive at the first temperature comprises heating or cooling the carrier substrate to the first temperature. In some methods, changing the temperature of the temperature-dependent adhesive comprises changing temperature of the carrier substrate to the second temperature.

Some methods of making a carrier substrate having a corrugated surface comprise providing the carrier substrate having a corrugated surface, disposing a micro-component on the carrier-substrate surface, etching the corrugated surface to reduce the area of the micro-component in contact with the corrugated surface. Some methods further comprise providing a transfer device (e.g., a stamp), contacting the transfer device to the micro-component, and removing the micro-component from the corrugated surface with the transfer device. The carrier-substrate surface can comprise a film, the film can be etched, and the removed micro-component can be a first micro-component. Methods of the present disclosure can further comprise removing and replacing the film after removing the micro-component from the carrier-substrate surface and disposing a second micro-component in direct contact with the carrier-substrate surface after etching and replacing the film, e.g., on the same, similar, or overlapping regions of the carrier substrate, e.g., the corrugated surface.

Some methods of transfer printing a micro-component according to illustrative embodiments of the present disclosure comprise providing a carrier substrate comprising a pattern of expandable structures, optionally increasing a volume of the expandable structures, contacting a micro-component to the expandable structures, reducing the volume of the expandable structures to reduce the area of the expandable structures in contact with the micro-component, and removing the micro-component from the expandable structures on the carrier substrate. Reducing the volume of the expandable structures can comprises drying, heating, or cooling the expandable structures. Some embodiments comprise increasing the volume of the expandable structures after reducing the volume of the expandable structures.

Embodiments of the present disclosure can comprise disposing a second micro-component in direct contact with the corrugated surface in a second region at least partially overlapping a first region of the carrier substrate on which the micro-component had been disposed after increasing the volume.

According to some embodiments of the present disclosure, a method of successively transfer printing micro-components from a carrier substrate comprises two or more iterations of: providing an initial micro-component adhered to a film disposed on the carrier substrate; removing the initial micro-component from the film with a transfer device; removing and replacing the film on the carrier substrate; and providing a next micro-component adhered to the replaced film at least partially in a same region of the carrier substrate as where the initial micro-component had been disposed. Removing the first micro-component can comprise permanently altering adhesiveness of the film (e.g., by etching the film). The film can have a corrugated contact surface for the micro-components.

Methods of transfer printing a micro-component according to the present disclosure can comprise providing a carrier substrate comprising holes, reducing air pressure to the holes, contacting a micro-component to the holes, increasing air pressure to the holes, and removing the micro-component from the carrier substrate, for example using a stamp contacted to the micro-component.

Methods of transfer printing a micro-component according to the present disclosure can comprise providing a carrier substrate, providing a micro-component adhered to the carrier substrate, providing a stamp having a stamp adhesion to the micro-component greater than a carrier-substrate adhesion to the micro-component, contacting the stamp to the micro-component, and removing the micro-component from the carrier substrate. The stamp can be a first stamp and methods of the present disclosure can comprise providing a second stamp having a second-stamp adhesion to the micro-component less than the carrier-substrate adhesion to the micro-component.

Methods of transfer printing a micro-component according to embodiments of the present disclosure can comprise providing a carrier substrate, providing a micro-component adhered to a first transfer device with a first transfer device adhesion, printing the micro-component to the carrier substrate with the first transfer device such that the micro-component is adhered to the carrier substrate with a carrier-substrate adhesion that is greater than the transfer device adhesion, contacting a second transfer device to the micro-component while the micro-component is adhered to the carrier substrate such that the micro-component is adhered to the second transfer device with a second transfer device adhesion that is greater than the carrier-substrate adhesion, and removing the micro-component from the carrier substrate with the second transfer device. In embodiments, (i) the first transfer device is a first stamp and the second transfer device is a second stamp, (ii) while the micro-component is adhered to the first stamp and to the carrier substrate, an area of the first stamp in contact with the micro-component is less than an area of the micro-component in contact with the carrier substrate, and (iii) while the micro-component is adhered to the second stamp and to the carrier substrate, an area of the second stamp in contact with the micro-component is greater than the area of the micro-component in contact with the carrier substrate. The carrier substrate can comprise a corrugated surface and the micro-component can contact the corrugated surface when the micro-component is adhered to the carrier substrate.

An area of the second stamp in contact with the micro-component can be less than an area of the micro-component in contact with the carrier substrate and an area of the first stamp in contact with the micro-component can be greater than the area of the micro-component in contact with the carrier substrate. The carrier substrate can be coated with a layer of PDMS with a carrier adhesion to the micro-component, the first stamp can comprise or can be coated with a layer of PDMS with a first-stamp adhesion to the micro-component, the second stamp can comprise or can be coated with a layer of PDMS with a second-stamp adhesion to the micro-component, the carrier adhesion can be greater than the second-stamp adhesion, and the first-stamp adhesion can be greater than the carrier adhesion, over an equivalent area to an equivalent material. The layer of PDMS on the first stamp can be more adhesive than the layer of PDMS on the carrier substrate and the layer of PDMS on the second stamp can be less adhesive than the layer of PDMS on the carrier substrate, over an equivalent area to an equivalent material. Some methods of the present disclosure comprise providing a target substrate and contacting the micro-component to a surface of the target substrate with the stamp. The surface of the target substrate can have an adhesion greater than the adhesion between the stamp and the micro-component, over an equivalent area to an equivalent material.

In embodiments, the carrier substrate is coated with a layer of PDMS (e.g., defining a corrugated surface) that provides the carrier-substrate adhesion to the micro-component, the first stamp comprises (e.g., is coated with) a layer of PDMS that provides the first-stamp adhesion to the micro-component, and the second stamp comprises (e.g., is coated with) a layer of PDMS with a second-stamp adhesion to the micro-component. In embodiments, (i) the layer of PDMS on the second stamp is more adhesive (e.g., tacky or sticky) than the layer of PDMS on the carrier substrate over an equivalent area to an equivalent material (e.g., the micro-component) and (ii) the layer of PDMS on the first stamp is less adhesive (e.g., tacky or sticky) than the layer of PDMS on the carrier substrate over an equivalent area to an equivalent material (e.g., the micro-component).

In some embodiments of the present disclosure, the corrugations are one-dimensional corrugations. In some embodiments of the present disclosure, the corrugations are two-dimensional corrugations.

Methods of the present disclosure can comprise providing a target substrate and contacting the micro-component to a surface of the target substrate with the second stamp such that the surface of the target substrate has an adhesion to the micro-component that is greater than the adhesion between the second stamp and the micro-component. The surface of the target substrate can be more adhesive (e.g., tacky or sticky) than the second stamp over an equivalent area to an equivalent material.

Embodiments of the present disclosure provide efficient and cost-effective micro-component assembly into an integrated system.

### BRIEF DESCRIPTION OF THE DRAWINGS

The foregoing and other objects, aspects, features, and advantages of the present disclosure will become more apparent and better understood by referring to the following description taken in conjunction with the accompanying drawings, in which:

FIG. 1A is a cross section of a carrier substrate with micro-components disposed on the carrier substrate according to illustrative embodiments of the present disclosure;

FIG. 1B is an exploded cross section of FIG. 1A according to illustrative embodiments of the present disclosure;

FIGS. 2-6 are cross sections of various carrier substrates with micro-components disposed on the carrier substrate according to illustrative embodiments of the present disclosure;

FIG. 7 is a flow diagram illustrating exemplary embodiments of the present disclosure;

FIGS. 8A-8C are successive cross sections illustrating sequential steps in exemplary methods according to illustrative embodiments of the present disclosure;

FIGS. 9A and 9B are flow diagrams illustrating exemplary embodiments of the present disclosure;

FIGS. 10A-10E are successive cross sections illustrating sequential steps in exemplary methods according to illustrative embodiments of the present disclosure;

FIGS. 11A-11F are successive cross sections illustrating sequential steps in exemplary methods according to illustrative embodiments of the present disclosure;

FIG. 12 is a flow diagram illustrating exemplary embodiments of the present disclosure;

FIG. 13A is a cross section of a carrier substrate with a film and micro-components disposed on the film according to illustrative embodiments of the present disclosure;

FIG. 13B is a cross section of a carrier substrate with a reduced film and micro-components disposed on the reduced film according to illustrative embodiments of the present disclosure;

FIG. 14 is a flow diagram illustrating exemplary embodiments of the present disclosure;

FIG. 15A is a cross section of a carrier substrate with a film and micro-components disposed on the film according to illustrative embodiments of the present disclosure;

FIG. 15B is a cross section of a carrier substrate with a reduced film and micro-components disposed on the reduced film according to illustrative embodiments of the present disclosure;

FIG. 16 is a flow diagram illustrating exemplary embodiments of the present disclosure;

FIG. 17A is a micrograph illustrating exemplary embodiments of the present disclosure;

FIG. 17B is a flow diagram illustrating exemplary embodiments of the present disclosure corresponding to the structure of FIG. 17A; and

FIGS. 18 and 19 are plan views of carrier substrates with one- and two-dimensional corrugations, respectively, according to illustrative embodiments of the present disclosure.

Features and advantages of the present disclosure will become more apparent from the detailed description set forth below when taken in conjunction with the drawings, in which like reference characters identify corresponding elements throughout. In the drawings, like reference numbers generally indicate identical, functionally similar, and/or structurally similar elements. The figures are not drawn to scale since the variation in size of various elements in the Figures is too great to permit depiction to scale.

### DETAILED DESCRIPTION OF CERTAIN EMBODIMENTS

The present disclosure provides, inter alia, carrier-substrate structures and methods for assembling micro-components onto the carrier substrate and removing micro-components from the carrier substrate, where the carrier substrate is non-native to the micro-components (e.g., the micro-components are constructed on one or more source substrates (e.g., semiconductor wafers or wafers comprising epitaxial layers disposed on a bulk material) and transferred to the carrier substrate. The micro-components can be transferred from respective source substrates to the carrier substrate using a variety of methods and structures (including micro-transfer printing) and removed from the carrier substrate using a variety of methods and structures (including micro-transfer printing). In some embodiments, micro-components are removed from the carrier substrate using micro-transfer printing with elastomeric stamps using rate-dependent adhesion. The carrier substrate can comprise a variety of structures according to a variety of embodiments of the present disclosure.

Components of the present disclosure can be micro-components, e.g., having a length or width no greater than two hundred, one hundred, fifty, twenty, ten, five, two, or one micron. Micro-components can be devices, e.g., individual devices such as integrated circuits, or assemblies of devices, for example devices made in different materials using different methods or materials, disposed on a common substrate or device (e.g., a component substrate). Embodiments of the present disclosure are not limited by the type, materials, functions, or applications of the component or micro-component.

Embodiments of the present disclosure provide manufacturing efficiency improvements by increasing the number of components transferred at a time from source wafers, reducing the number of transfer operations, by transferring a dense configuration of components from the source wafers to an intermediate carrier substrate. Different components native to different source wafers can be transferred to the intermediate carrier substrate to form groups of different kinds of components in a relatively high-density spatial configuration. The different kinds of components can then be transferred in groups from the intermediate carrier substrate in a sparse configuration to a target destination substrate. The different components in the groups can be components from and native to different source wafers, e.g., comprising different materials, such as different semiconductor materials, such as silicon, Gan GaAs, and InP. If the components were transferred directly from the source wafer to the target substrate, only a sparse configuration of components (e.g., fewer components) could be transferred at a time, increasing the number of transfer operations, reducing manufacturing throughput, and increasing costs. In contrast, embodiments of the present disclosure increase manufacturing throughput and reduce costs.

Embodiments of the present disclosure provide an intermediate carrier substrate to which components (e.g., micro-components) can be transferred from a source wafer. Components can be adhered to the intermediate carrier substrate without the use of tether-anchor structures that suspend devices over the intermediate carrier substrate. Instead, as disclosed herein, components can be adhered to and in contact with the intermediate carrier substrate or layers disposed on the intermediate carrier substrate in a variety of ways using a variety of methods and structures and can be removed directly from the intermediate carrier substrate using different techniques, including using a rate-dependent, elastomeric stamp (or stamp post of an elastomeric stamp).

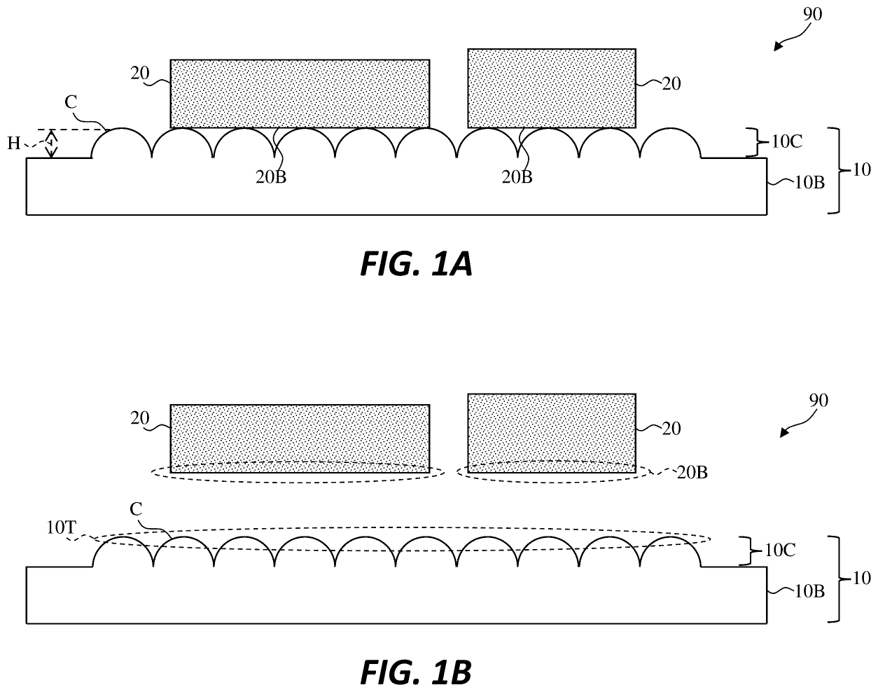

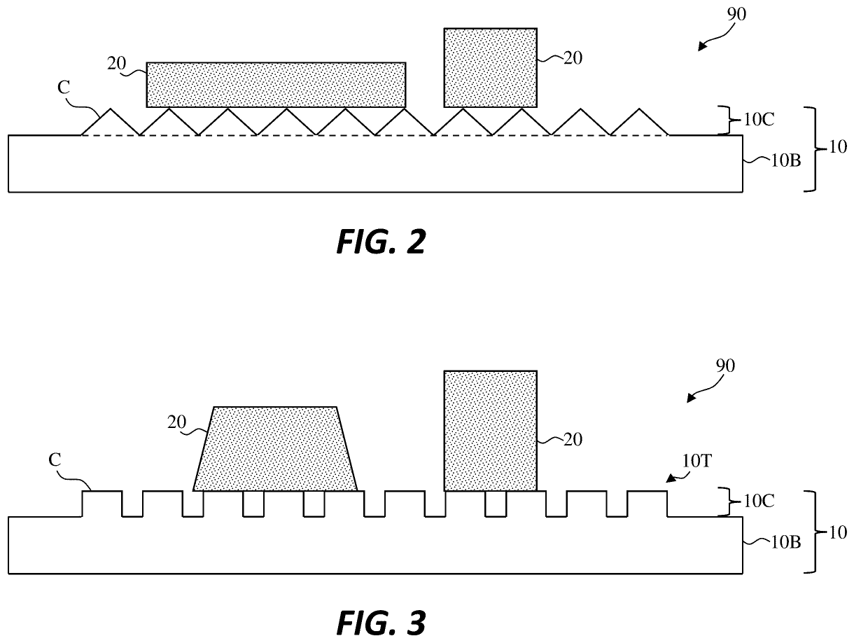

In embodiments of the present disclosure and as illustrated in FIG. 1A, exploded FIG. 1B, and FIGS. 2-6, a micro-component substrate structure 90 comprises a carrier substrate 10 (e.g., an intermediate substrate onto which micro-components are transferred and then removed in groups) having a corrugated surface 10C and a micro-component 20 having a bottom surface 20B disposed on corrugated surface 10C. Bottom side 20B of micro-component 20 is the side of micro-component 20 adjacent to carrier substrate 10, e.g., the closest side of micro-component 20 to carrier substrate 10. Corrugated surface 10C can have a variety shapes, for example shaped into wavy folds or alternating furrows and ridges in one or two dimensions on or in a surface of a bulk substrate 10B (bulk layer 10B) of carrier substrate 10. Each wavy fold or ridge forms a structure that is a corrugation C having a height (or depth) H. The height H of each corrugation can be a few microns, for example no greater than one hundred, fifty, twenty, ten, five, two or one micron. Corrugations C can comprise a same material as the bulk layer 10B or can comprise a different material from bulk layer 10B. Corrugations C can be unitary or can comprise a film coated over the structures to form corrugated surface 10C. The bulk material can be rigid or less flexible than corrugations C. Corrugations C can be formed by, for example, photolithographic processing of bulk layer 10B. Bulk layer 10B can be a contiguous layer that includes corrugations C. Corrugations C (e.g., and bulk layer 10B) can comprise an oxide, silicon, or glass.

According to embodiments of the present disclosure, by definition corrugated surface 10C is non-planar. In contrast, device bottom 20B can be substantially planar or at least more planar than corrugated surface 10C. Thus, only a portion of device bottom 20B of micro-component 20 disposed on corrugated surface 10C will be in direct contact with corrugated surface 10C and only a portion of corrugated surface 10C will be in direct contact with device bottom 20B, for example along and on the tops (in a direction away from bulk substrate 10B and toward micro-component 20) of corrugations C. Micro-component 20 can be adhered to corrugated surface 10C by chemical or van der Waal's forces. By adjusting the size, height, shape, spatial density, and number of corrugations C in corrugated surface 10C (for example corrugations C per linear distance or per area), the area of corrugated surface 10C in direct contact with device bottom 20B can be controlled and, hence, the adhesion between corrugated surface 10C and device bottom 20B of micro-component 20. Moreover, and as shown in FIGS. 1A-6, in embodiments only a portion of one or more corrugations C is in contact with micro-component 20. That is, micro-component 20 can contact only some corrugations C of corrugated surface 10C. In some embodiments, multiple corrugations C are in direct contact with device bottom 20B of micro-component 20. Thus, the adhesion between corrugated surface 10C and device bottom 20B of micro-component 20 can also depend on the size of micro-component 20 or area of device bottom 20B. In some embodiments, multiple micro-components 20 are disposed on and in direct contact with a common corrugated surface 10C of a common carrier substrate 10. The multiple micro-components 20 can be arranged in a regular array or groups of micro-components 20 can be arranged in a regular array on carrier substrate 10 and can have the same shape or size or have different shapes or sizes (as shown in FIGS. 1A-6).

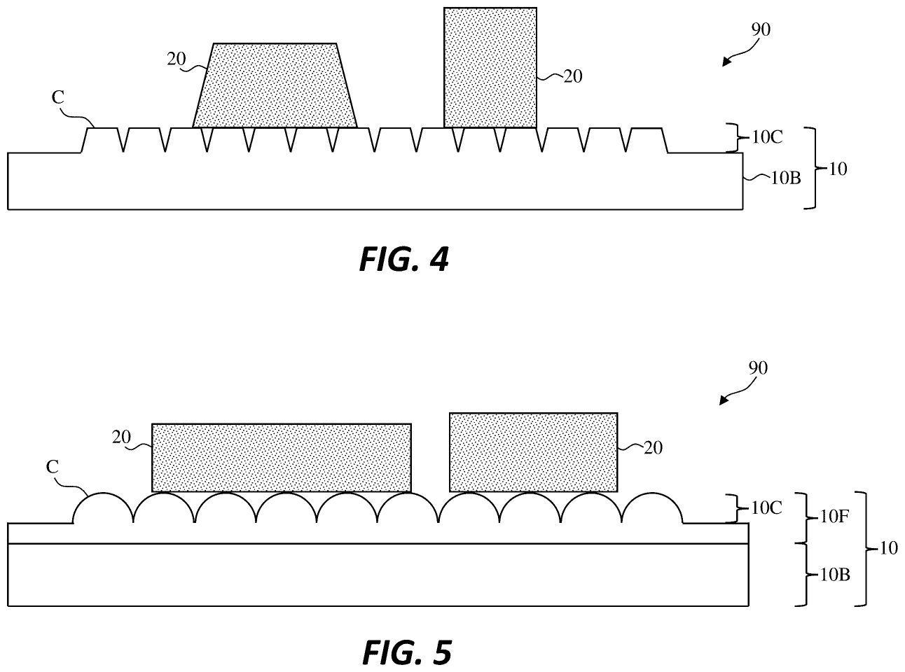

FIGS. 1A and 1B are cross sections illustrating corrugations C shaped into cylindrical lenslets (extending in one direction across a surface of carrier substrate 10) or shaped into portions of a sphere (e.g., hemispheres) extending in two directions across a surface of carrier substrate 10, for example forming a lenslet array. FIG. 2 illustrates corrugations C forming triangular ridges (extending in one direction across a surface of carrier substrate 10) or pyramids or tetrahedrons (extending in two directions across a surface of carrier substrate 10). FIG. 3 illustrates corrugations C forming rectangular structures (extending in one direction across a surface of carrier substrate 10) or cubes or portions of a cube (extending in two directions across a surface of carrier substrate 10). FIG. 4 illustrates corrugations C forming trapezoidal structures (extending in one direction across a surface of carrier substrate 10) or trapezoidal solids having trapezoidal cross sections (extending in two directions across a surface of carrier substrate 10). FIG. 5 illustrates corrugations C forming triangular ridges (extending in one direction across a surface of carrier substrate 10) or pyramids or tetrahedrons (extending in two directions across a surface of carrier substrate 10) that are coated with a film 10F.

Film 10F can comprise a film material and bulk substrate 10B can comprise a bulk material different from the film material. For example, the bulk material can be silicon, the film material can be PDMS, or both. Bulk substrate 10B can be rigid and film 10F can be flexible or more flexible than bulk substrate 10B. For example, bulk layer 10B can be substantially incompressible and film 10F can be relatively compressible compared to bulk layer 10B. In some embodiments, corrugations C are substantially incompressible, for example where corrugations C are formed on bulk layer 10B by photolithographic processing. Film 10F can be flexible or compressible, or film 10F can be relatively flexible or compressible compared to bulk layer 10B. In some embodiments, corrugations C or portions (e.g., a layer of film 10F) of corrugations C are compressible.

Film 10F material can have a thickness of no greater than ten, five, two, one, one half, one fifth, or one tenth micron and can have a thickness no greater than height H of corrugations C. Corrugations C can be flexible or can comprise a flexible film 10F coating C. Corrugations C can contact each other, for example in some embodiments there is no space between corrugations C in a direction parallel to a surface of bulk layer 10B or bottom side 20B of micro-component 20, as shown in FIGS. 1A, 1B, 2, 4, 5, 6 but not FIG. 3 (e.g., corrugations C are not spaced apart or corrugations C are touching). In embodiments, corrugations C are not rectangular or do not have a rectangular cross section in a direction orthogonal to bottom side 20B or micro-component 20. Corrugations C can comprise structures that extend from a surface of bulk layer 10B in a direction toward micro-component 20.

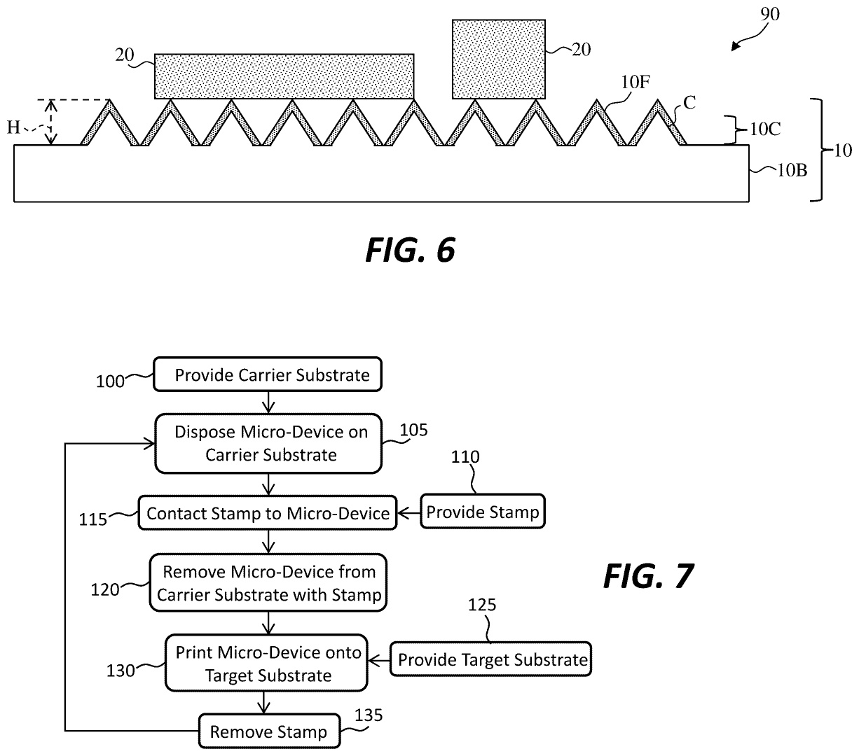

In some embodiments of the present disclosure, carrier substrate 10 can comprise a material and corrugations C in corrugated surface 10C of carrier substrate 10 comprise the same material, for example in FIGS. 1A, 1B, 2-5. Carrier substrate 10 material that is not part of corrugated surface 10C can comprise bulk substrate 10B (or bulk layer 10B) comprising bulk material. In such embodiments, carrier substrate 10 can comprise a substrate (e.g., a wafer) comprising material found in the semiconductor and display industries. Corrugated surface 10C can be formed in or on bulk substrate 10B using photolithographic methods and materials, e.g., by pattern-wise etching a surface of bulk substrate 10B to form topographical structures comprising corrugations C of corrugated surface 10C. In some embodiments and as shown in FIG. 6, corrugations C comprise a coating of film 10F, for example by evaporation, spray, or spin coating, on a structure formed on bulk layer 10B. Film 10F can be relatively thin (e.g., no greater than ten, five, two, or one micron, or less than one micron, for example five, ten, twenty, fifty, one hundred, two hundred, or five hundred nm). Film 10F can be a different material (e.g., an organic polymer or a different inorganic material such as an oxide or nitride, e.g., silicon dioxide or silicon nitride) from bulk substrate 10B (e.g., an inorganic material) that has different surface properties, such as different surface energies useful in controlling the adhesion of micro-components 20 to corrugated surface 10C and takes its shape from the underlying structures of carrier substrate 10.

In some embodiments and as shown in FIG. 6, film 10F disposed on structured bulk substrate 10B can form a coated surface in contact with micro-components 20. In some embodiments, corrugations C comprise a structured film 10F. In some embodiments, film 10F can be disposed as a substantially planar film 10F and then processed to form corrugations C of corrugated surface 10C, for example by photolithographic processing, imprinting, or molding. Thus, in some embodiments, corrugations C comprise film 10F coated on structures formed on or in bulk layer 10.

Film 10F can be disposed as a liquid, processed (e.g., by imprinting), and cured to form a solid or rigid corrugated surface 10C. Film 10F can be thinner than height H of corrugations C. Such techniques can require fewer and less expensive processing steps than a photolithographic process applied to bulk substrate 10B. Film 10F can be a different material (e.g., an organic polymer) from bulk substrate 10B (e.g., an inorganic material) that has different surface properties, such as different surface energies useful in controlling the adhesion of micro-components 20 to corrugated surface 10C. Furthermore, in some embodiments film 10F can be removed (e.g., by etching or dissolving) and replaced to renew film 10F after use.

Carrier substrate 10 can comprise inorganic materials, semiconductors, such as silicon, glass, polymer, sapphire, quartz, ceramics, or metal, but is not limited to these. Topographical structures (e.g., corrugations C) can be formed in carrier substrate 10 (e.g., bulk substrate 10B) by coating bulk substrate 10B with a photoresist, patterning the photoresist by exposing it to patterned light (e.g., light exposure through a mask), removing exposed or unexposed photoresist, etching the exposed surface of carrier substrate 10, and stripping the remaining photoresist. Film 10F can be or comprise organic materials such as polymers, resins, epoxies, and polydimethylsiloxane, (PDMS), but is not limited to these.

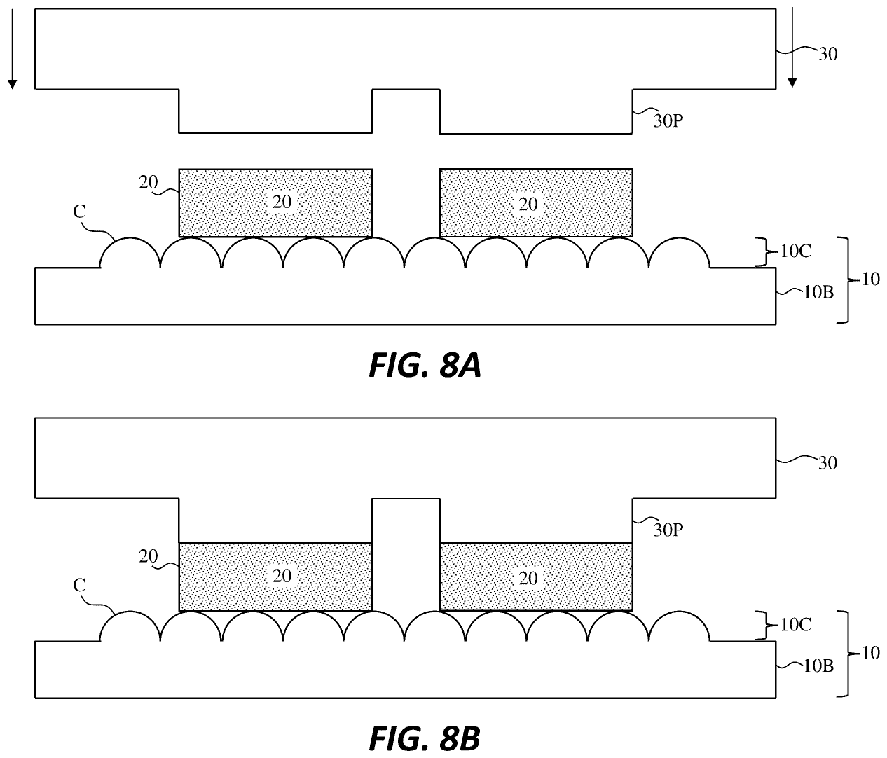

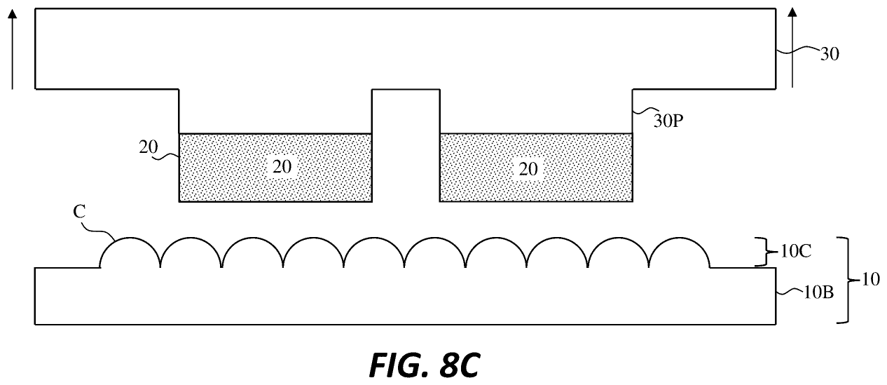

According to embodiments of the present disclosure and as illustrated in the FIG. 7 flow diagram and successive structures of FIGS. 8A-8C, a method of transfer printing a micro-component 20 can comprise providing a carrier substrate 10 in step 100, disposing one or more micro-components 20 onto corrugated surface 10C of carrier substrate 10 to form micro-component substrate structure 90 in step 105, and providing a stamp 30 in step 110. A motion-and-optics optomechatronic machine can control the movement of stamp 30 with respect to carrier substrate 10 and micro-component substrate structure 90, as shown in FIG. 8A. Stamp 30 (e.g., a stamp post 30P of stamp 30) is moved into physical contact with a top side of micro-component 20 opposite bottom side 20B in step 115 and as shown in FIG. 8B. Micro-component 20 is then removed from carrier substrate 10 in step 120 using stamp 30 and the motion-and-optics optomechatronic machine and as shown in FIG. 8C. Micro-component 20 on stamp post 30P can then be printed onto a target substrate (provided in step 125) in step 130 and stamp 30 removed. An adhesion between micro-component 20 and the target substrate can be greater than adhesion between stamp 30 and micro-component 20. Stamp 30 is then removed in step 135 and the process can repeat for new micro-components 20 disposed on carrier substrate 10.

For this process to work, the adhesion between stamp post 30P and micro-component 20 must be greater than the adhesion between micro-component 20 and corrugated surface 10C of carrier substrate 10 and less than the adhesion between micro-component 20 and the target substrate. The adhesion between stamp post 30P and micro-component 20 can be controlled, at least in part, by controlling the material composition of stamp post 30P, the area of stamp post 30P in contact with micro-component 20, and the movement of stamp 30 (e.g., the speed and acceleration of stamp post 30P) with respect to micro-component 20 or carrier substrate 10. The adhesion between micro-component 20 and carrier substrate 10 can be controlled, at least in part, by controlling the shape, size, and spatial density of corrugations C of corrugated surface 10C, and a material of the surface of corrugations C in contact with micro-component 20 as well as a material of bottom surface 20B of micro-component 20. Other operating characteristics can also affect adhesion, for example temperature and humidity. In some embodiments, corrugated surface 10C (e.g., film 10F) is processed to reduce the adhesion between corrugated surface 10C and device bottom 20B, for example by heating or cooling corrugated surface 10C or film 10F or by exposing corrugated surface 10C or film 10F to electromagnetic radiation (e.g., ultraviolet or infrared radiation) to modify the nature of corrugated surface 10C or film 10F.

The adhesion force between carrier substrate 10 and micro-component 20 can also be controlled by a force used to press micro-component 20 against carrier substrate 10 when disposing micro-component 20 on carrier substrate 10 (e.g., with a stamp). If corrugated surface 10C is flexible (e.g., corrugations C are flexible or are coated with a flexible film 10F, as shown in FIG. 6), corrugated surface 10C can deform in response to the pressure so that a greater bottom-side 20B area of micro-component 20 contacts corrugated surface 10C, increasing the adhesion between micro-component 20 and carrier substrate 10. Thus, in some embodiments, the step of disposing micro-component 20 on corrugated surface 10C increases the contact area between micro-component 20 and corrugated surface 10C. Moreover, in some embodiments, corrugated 10C is deformed when in contact with micro-component 20 and has a different shape than when not in contact with micro-component 20.

According to embodiments of the present disclosure, micro-components 20 can be disposed on corrugated surface 10C by constructing micro-components 20 on a native source wafer (substrate) and then transferring micro-components 20 from their native source wafer to corrugated surface 10C using laser-induced forward transfer (LIFT), laser ablation, or electrostatic stamps. In some embodiments, micro-components 20 are transferred from their native source wafer using micro-transfer printing with stamp 30 where the adhesion between stamp post 30P is strong enough to enable micro-component 20 removal from its native source wafer but weak enough to dispose micro-component 20 onto carrier substrate 10. The relative adhesion can be controlled in part by a material of corrugated surface 10C or by the relative area of stamp post 30P in contact with micro-component 20 compared to an area of micro-component 20 in contact with corrugated surface 10C. Given equivalent-adhesion materials (e.g., where stamp post 30P and film 10F both comprise similar PDMS), a stamp post 30P area of stamp 30 in contact with micro-component 20 that is smaller than an area of micro-component 20 in contact with corrugated surface 10C can result in micro-component transfer to corrugated surface 10C when micro-component 20 is in contact with both stamp post 30P and corrugated surface 10C and then stamp 30 is removed.

In embodiments of the present disclosure, a carrier substrate 10 can be reused multiple times to successively receive micro-components 20 that are then removed from carrier substrate 10, for example by micro-transfer printing with a stamp 30. Thus, embodiments of the present disclosure can comprise sequentially disposing a first micro-component 20 onto carrier substrate 10, removing first micro-component 20 from carrier substrate 10, disposing a second micro-component 20 onto carrier substrate 10 after first micro-component 20 is removed from carrier substrate 10, and removing second micro-component 20 from carrier substrate 10.

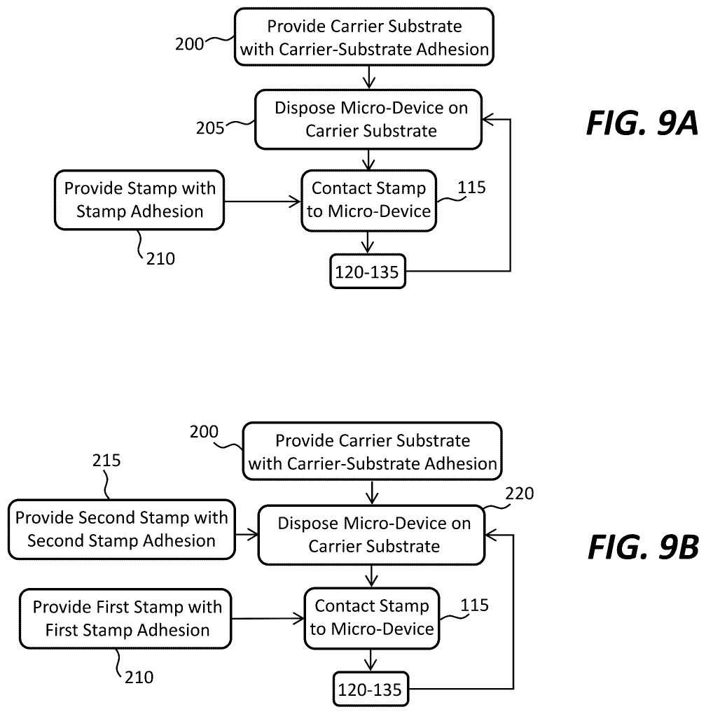

In some embodiments of the present disclosure, carrier substrate 10 is not corrugated and has a substantially planar surface. Carrier substrate 10 can be coated with a film 10F, for example to control an adhesion of carrier substrate 10 to a micro-component 20 with respect to an adhesion of stamp 30 (or stamp post 30P) to micro-component 20. By controlling the relative adhesion to micro-component 20 by carrier substrate 10 and stamp 30, micro-component 20 can be transferred from carrier substrate 10 to stamp 30. Thus, according to embodiments of the present disclosure and as illustrated in FIG. 9A, a method of transfer printing a micro-component 20 comprises providing a carrier substrate 10 in step 200, providing a micro-component 20 adhered to carrier substrate 10 (for example by any of micro-transfer printing, laser-induced forward transfer, laser ablation, electro-static stamp transfer, or micro-transfer printing) in step 205, providing a stamp 30 having a stamp adhesion to micro-component 20 greater than a carrier-substrate adhesion to micro-component 20 in step 210, contacting stamp 30 (e.g., contacting stamp post 30P) to micro-component 20 in step 115, and removing micro-component 20 from carrier substrate 10 in step 120, as described in FIG. 7, because the stamp adhesion to micro-component 20 is greater than the carrier-substrate adhesion to micro-component 20. Micro-component 20 can then be transferred onto a target substrate as further described in FIG. 7 in steps 125-135. The process can then be repeated by disposing further micro-components 20 onto carrier substrate 10 (in step 205). If film 10F eventually loses it adhesive qualities or is otherwise contaminated, for example with particulates, it can be stripped (e.g., by a field etch) and recoated.

In some embodiments of the present disclosure and as illustrated in FIG. 9B, a second stamp 30B can be used to transfer micro-components 20 from a native source substrate (wafer). First stamp 30A can have a first-stamp adhesion to micro-component 20, second stamp 30B can have a second-stamp adhesion to micro-component 20, and carrier substrate 10 can have a carrier-substrate adhesion to micro-component 20. The second-stamp adhesion can be less than the carrier-substrate adhesion and the carrier-substrate adhesion can be less than the first-stamp adhesion. Thus, as shown in FIG. 9B, a method of transfer printing a micro-component 20 comprises providing a carrier substrate 10 in step 200 and providing a micro-component 20 adhered to carrier substrate 10 in step 220, for example by micro-transfer printing with a second stamp 30B provided in step 215. Micro-component 20 will adhere to carrier substrate 10 because the second-stamp adhesion to micro-component 20 is less than the carrier-substrate adhesion to micro-component 20. First stamp 30A having a first-stamp adhesion to micro-component 20 greater than a carrier-substrate adhesion to micro-component 20 is provided in step 210 and contacted to micro-component 20 in step 115. Micro-component 20 is removed from carrier substrate 10 in step 120, as described in FIG. 7, because the stamp adhesion to micro-component 20 is greater than the carrier-substrate adhesion to micro-component 20. Micro-component 20 can then be transferred to a target substrate as further described in FIG. 7 in steps 125-135. The process can be repeated by disposing further micro-components 20 onto carrier substrate 10 (in steps 205 or 220).

The processes described (and generally for micro-transfer printing) rely on the relative adhesion between stamps 30 (e.g., first and second stamps 30A and 30B) and micro-components 20 and between carrier substrate 10 and micro-components 20. The relative adhesions can be controlled by controlling the relative area of contacting surface\s or by the materials that are in contact with micro-components 20, especially the materials of stamps 30 (or stamp posts 30P) and carrier substrate 10 (or film 10F). The relative contact area can be controlled by the size and spatial density of corrugations Con carrier substrate 10 and the size of stamp posts 30P. The materials can be controlled by constructing stamps 30 (or stamp posts 30P) and films 10F (or bulk material) of carrier substrate 10 using suitable materials (such as PDMS with various concentrations of constituent materials, or other materials such as adhesives). Some of the materials can be reused multiple times for multiple transfer steps and some of the materials can be processed each time they are used and replaced for subsequent transfer steps.

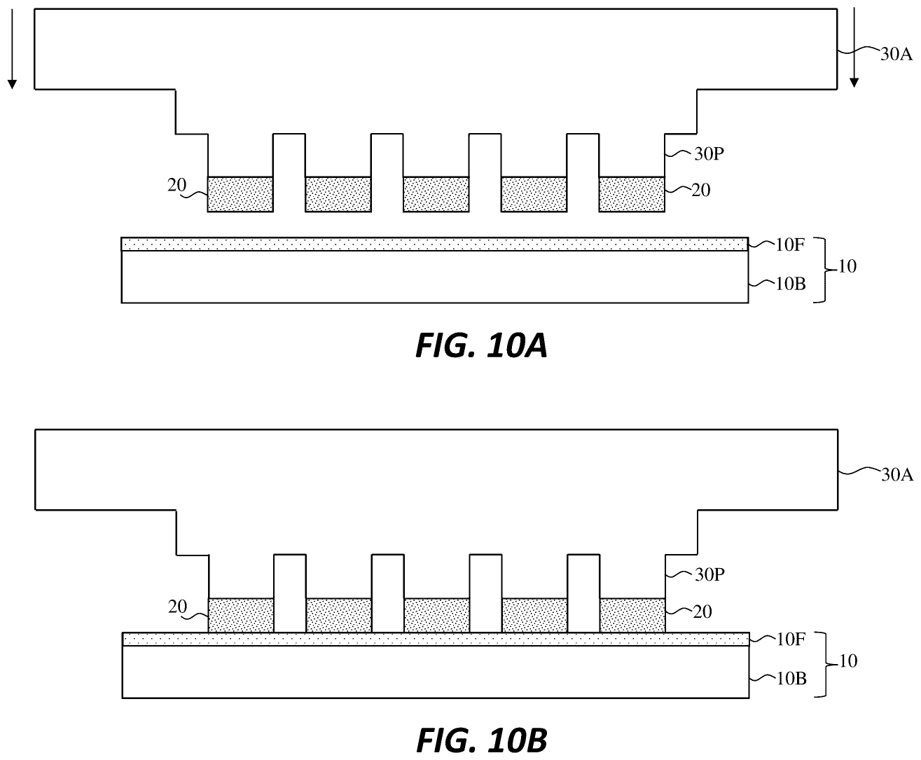

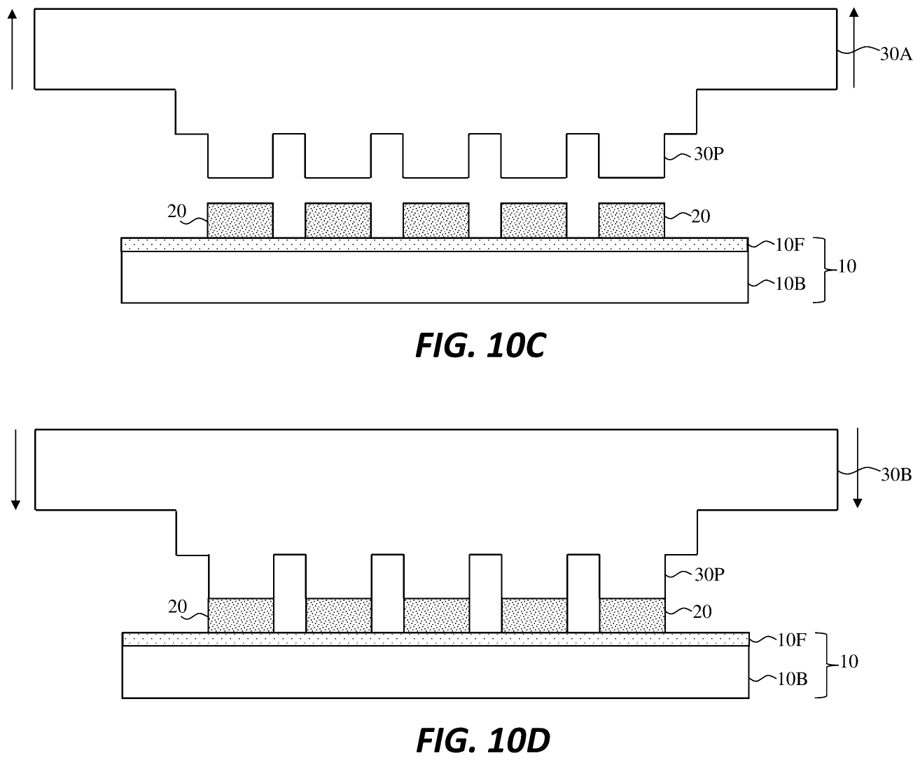

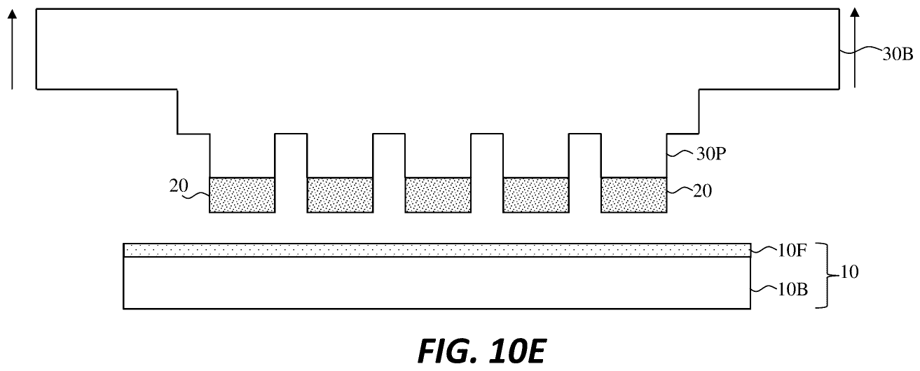

FIGS. 10A-10E illustrate embodiments of the present disclosure in which different materials or material concentrations are used to control relative adhesion to micro-component 20. As shown in FIG. 10A, a first stamp 30A has micro-components 20 adhered to stamp posts 30P. Stamp posts 30P of first stamp 30A comprise or are coated with a material such as PDMS that adheres micro-components 20 to stamp posts 30P with a first-stamp adhesion. Carrier substrate 10 can comprise a film 10F forming a substantially planar surface of carrier substrate 10 (or can have corrugations C in a corrugated surface 10C). Stamp 30 is moved toward carrier substrate 10 to contact micro-components 20 to film 10F, as shown in FIG. 10B and indicated in step 220 of FIG. 9B. Micro-components 20 are adhered to film 10F with a carrier-substrate adhesion that is stronger than the first-stamp adhesion. Film 10F can comprise, for example PDMS, that is formulated to be more adhesive to micro-components 20 than a PDMS stamp post 30P is to micro-components 20, so that micro-components 20 will adhere to film 10F of carrier substrate 10 when first stamp 30A is removed from carrier substrate 10, as shown in FIG. 10C. Stamp posts 30P of second stamp 30B comprise or are coated with a material such as PDMS that adheres micro-components 20 to stamp posts 30P with a second-stamp adhesion greater than the carrier-substrate adhesion and contact micro-components 20 on carrier substrate 10 to adhere micro-components 20 to stamp posts 30P of second stamp 30B with the second-stamp adhesion, as shown in FIG. 10D in step 115 of FIGS. 7, 9A, and 9B. Second stamp 30B is then removed with micro-components 20 as shown in FIG. 10E in step 120 of FIGS. 7, 9A, and 9B. According to embodiments and as shown in FIG. 7, micro-components 20 can then be micro-transfer printed to a target substrate in steps 130 and 135. Note that the appellations first stamp and second stamp are arbitrary and can be exchanged.

PDMS having different adhesions (tackiness) can be made by mixing different relative quantities of an elastomer (e.g., Sylgard 184) with the corresponding curing agents and diluents, for example toluene, xylene, hexane, or silicone fluids, curing at different temperatures, and rinsing with different materials to remove any uncrosslinked material components, e.g., with toluene, xylene, hexane, or silicone fluids. Stamps 30 can also have different Young's moduli and corresponding different adhesions (typically a greater Young's modulus corresponds to reduced adhesion). Thus, by making first stamp 30A stamp posts 30P with a first mixture of PDMS pre-cursor materials, making second stamp 30B stamp posts 30P with a second mixture of PDMS pre-cursor materials, and making film 10F of carrier substrate 10 with a third mixture of PDMS pre-cursor materials, suitable relative adhesive qualities (tackiness) can be achieved. In some embodiments, carrier substrate 10 does not require a film 10F (with or without corrugations C) and bulk layer 10B (with or without corrugations C) can have the requisite tackiness (adhesion to micro-component 20), e.g., from vander Waal's forces.

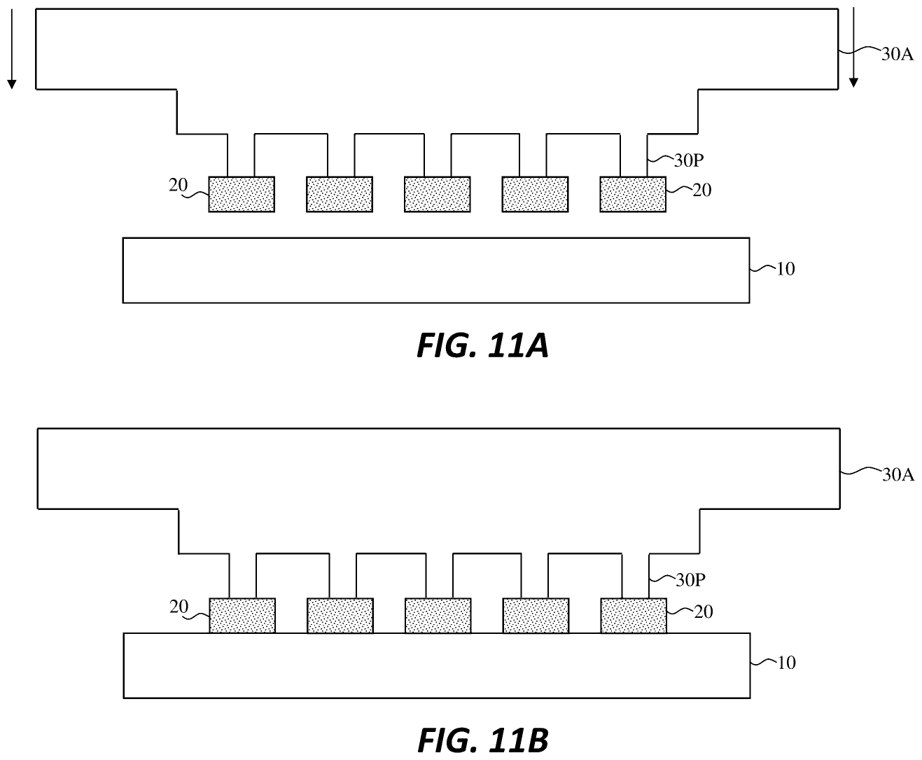

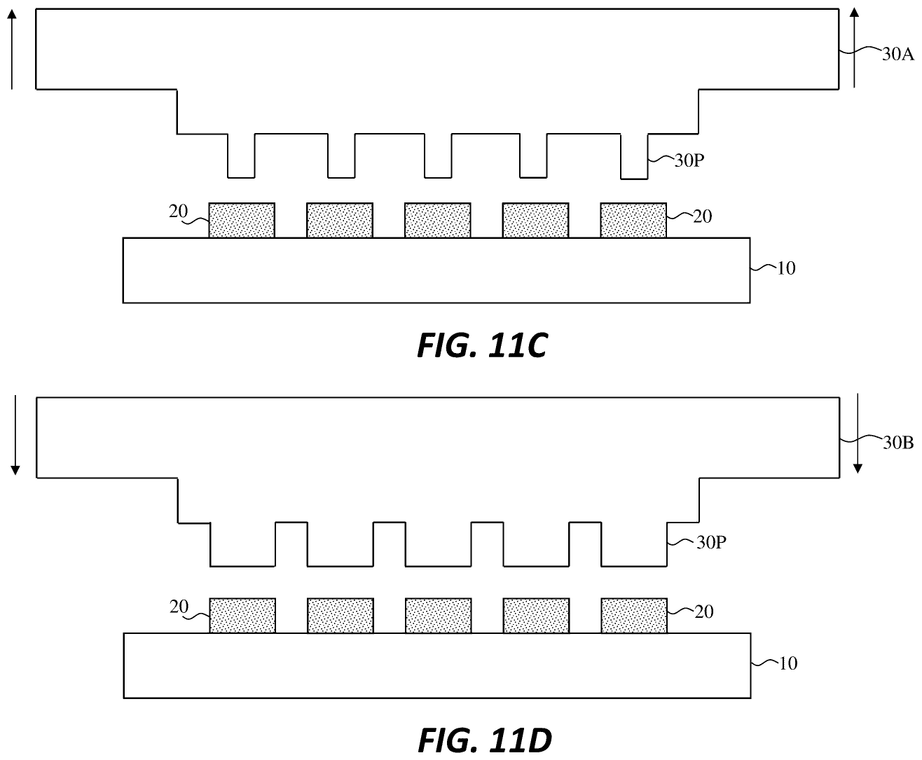

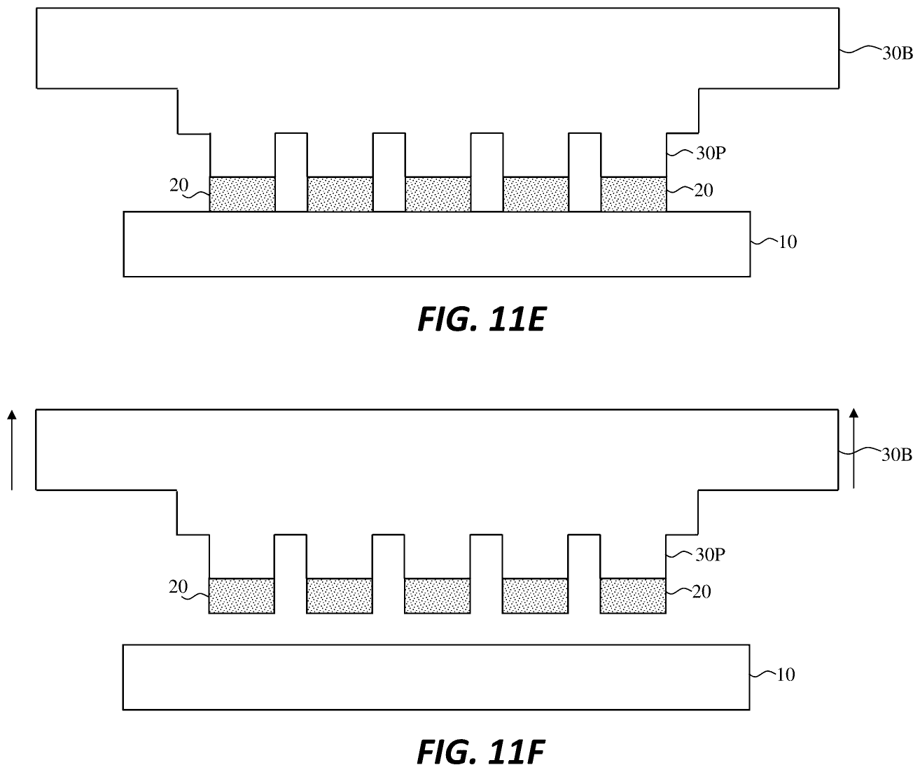

FIGS. 11A-11F illustrate embodiments of the present disclosure in which different contact areas between a stamp post 30P and micro-component 20 (and optionally between carrier substrate 10 having corrugated surface 10C with corrugations C to micro-component 20) are used to control relative adhesion to micro-component 20. As shown in FIG. 11A, a first stamp 30A has micro-components 20 adhered to stamp posts 30P having a relatively smaller area in contact with micro-components 20. The relatively smaller contact area provides relatively smaller first-stamp adhesion between micro-component 20 and stamp post 30P of first stamp 30A. A single stamp post 30P (e.g., one stamp post 30P) can be used to contact each micro-component 20 to carefully control the adhesion and ensure that stamp 30A can also pick up micro-components 20 from a native micro-component 20 source wafer. Micro-components 20 on first stamp 30A are contacted to carrier substrate 10 (with or without corrugated surface 10C or film 10F) as shown in FIG. 11B and step 220 of FIG. 9B. The carrier-substrate adhesion between micro-components 20 and carrier substrate 10 is greater than the first-stamp adhesion so that, when first stamp 30A is removed from carrier substrate 10, micro-components 20 adhere to carrier substrate 10, as shown in FIG. 11C. Second stamp 30B has a relatively larger stamp post 30P area than first stamp 30A, as shown in FIG. 11D, so that when stamp posts 30P of second stamp 30B contact micro-components 20 as shown in FIG. 11E in step 115 of FIGS. 9A, 9B, and 7, micro-components 20 adhere with a second-stamp adhesion greater than the carrier-substrate adhesion. Second stamp 30B is then removed with micro-components 20 in step 120 and as shown in FIG. 11F. According to embodiments and as shown in FIG. 7, micro-components 20 can then be micro-transfer printed to a target substrate in steps 130 and 135. The process can be repeated for multiple sequential transfers of micro-components 20, for example first transferring first micro-components 20 and then second transferring second micro-components 20. Note that the appellations first stamp and second stamp are arbitrary and can be exchanged.

Embodiments of the present disclosure can combine materials with different adhesive qualities for stamp posts 30P of first and second stamps 30A, 30B and carrier substrate 10 with or without corrugations C and relative contact areas of stamp posts 30P of first and second stamps 30A, 30B and carrier substrate 10 with or without corrugations to micro-component 20. Corrugations C of carrier substrate 10 can be used alone, stamps posts 30P with different areas in contact with micro-component 20 can be used alone, stamps posts 30P or films 10F with different materials can be used alone, or any combination of these can be used together.

In some embodiments of the present disclosure, film 10F can be processed to modify the adhesion between micro-components 20 and film 10F of carrier substrate 10. (This can also be done in combination with any of the methods described above incorporating films 10F.) For example, the adhesiveness of some materials can be permanently or temporarily modified by heat or exposure to electromagnetic radiation, including PDMS, heat tape, or dicing tape. For some materials, the change in adhesive qualities is permanent and the material must be replaced for any subsequent transfers. Other materials, such as PDMS, can repeatedly change their adhesive qualities in response to heating and cooling.

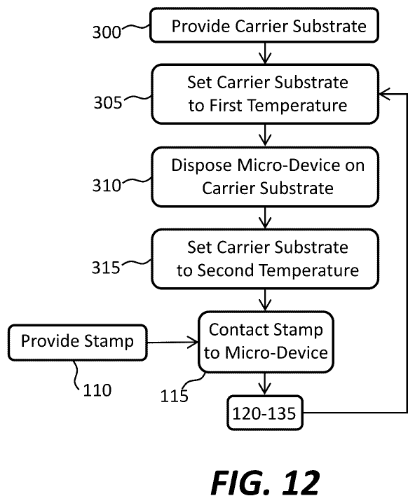

According to methods of the present disclosure and as illustrated in FIG. 12, a method of transfer printing micro-component 20 comprises providing a carrier substrate 10 coated with a temperature-dependent adhesive in step 300 (e.g., film 10F), heating or cooling carrier substrate 10 to a first temperature in step 305 to strengthen or maintain temperature-dependent adhesive adhesion, contacting a micro-component 20 to the temperature-dependent adhesive on carrier substrate 10 at the first temperature in step 310, for example by micro-transfer printing, changing the temperature of carrier substrate 10 to a second temperature different from the first temperature to weaken the adhesion of the temperature-dependent adhesive in step 315, and removing micro-component 20 from the temperature-dependent adhesive on carrier substrate 10 in step 115. Micro-component 20 can then be printed with stamp 30 in steps 120-135. Alternatively, a temperature of stamp 30 (or first and second stamps 30A, 30B) or micro-component 20 can be modified. In embodiments, the relative temperature between micro-component 20, stamps 30, and carrier substrate 10 is controlled to enable suitable adhesion for different steps in the assembly process.

A temperature-dependent adhesive has different adhesive qualities at different temperatures, for example PDMS, can have different adhesive qualities at different temperatures. In some embodiments, a cold layer of PDMS (e.g., a film 10F) on carrier substrate 10 can adhere more strongly than a warmer layer. Moreover, in some embodiments micro-transfer printing is a rate-dependent process that adheres stronger to a surface when pulled quickly from the surface and weaker when pulled slowly. This adhesive attribute of visco-elastic (elastomeric) materials such as PDMS can be used separately or coupled with temperature-dependency attributes to increase the process window size for adhering and removing micro-components 20 from the PDMS surfaces such as a film 10F on carrier substrate 10. For example, adhesion between micro-component 20 and film 10F (comprising PDMS) is increased when film 10F is cold and moves quickly and decreased between stamp 30 and micro-component 20 when stamp 30 is warm and moves slowly. To remove micro-component 20 from film 10F with stamp 30, stamp 30 can move quickly and be cold while film 10F can be warm. The disposition and removal process can be iteratively repeated for successive micro-component 20.

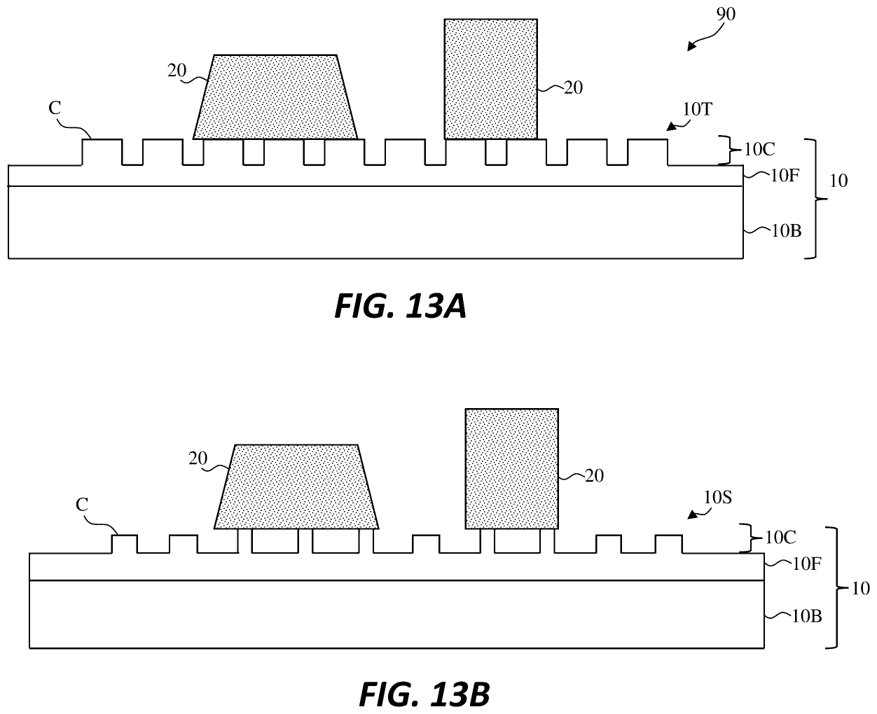

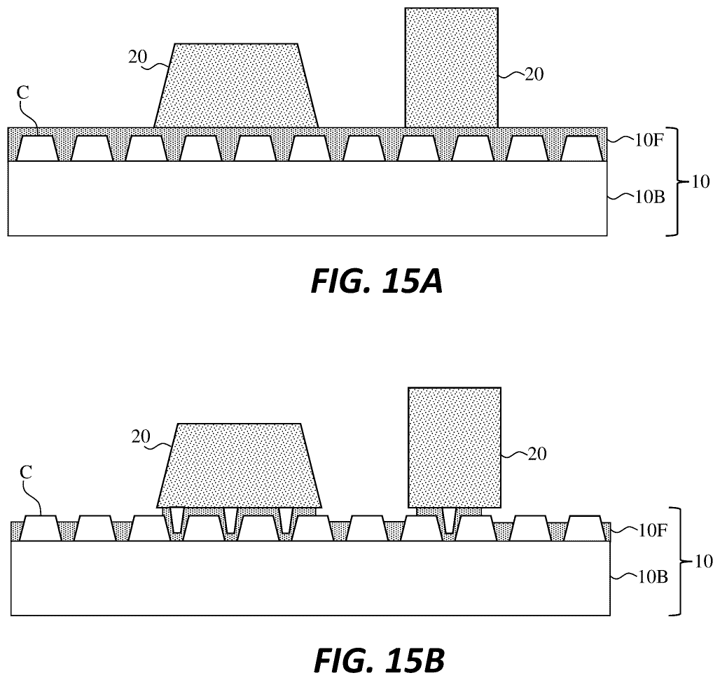

In some embodiments of the present disclosure and as illustrated in FIG. 15, film 10F is processed to change its volume or area in contact with, and adhesion to, micro-component 20 by etching film 10F. FIG. 13A illustrates micro-components 20 disposed on a corrugated surface 10C of film 10F. Exposed portions of corrugations C in film 10F contacting micro-component 20 can be removed by partially etching or dissolving film 10F to reduce the area of film 10F in contact with micro-component 20, as shown in FIG. 13B. The reduced area of film 10F in contact with micro-component 20 reduces the adhesion between film 10F and micro-component 20, so that micro-component 20 can be removed easier from film 10F by contacting micro-component 20 with stamp 30 in a micro-transfer printing process. The process can be repeated by removing and replacing film 10F after removing micro-component 20 from film 10F and disposing a successive micro-component 20 on replaced film 10F.

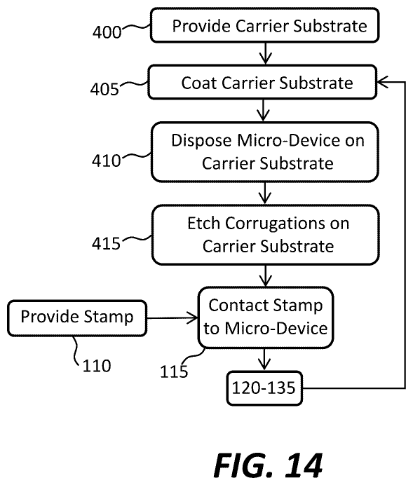

Thus, according to methods of the present disclosure and as illustrated in FIG. 14, a carrier substrate 10 with structures is provided in step 400, and a film 10F is coated in step 405 so that corrugations C comprise a coating of film 10F. Alternatively, carrier substrate 10 bulk layer 10B is no structured, corrugations C are instead imprinted or otherwise formed, e.g., by photolithography, in film 10F. Micro-component 20 is disposed on carrier substrate 10 in contact with corrugations C of film 10F in step 410, film 10F is decreased in size or area (e.g., by etching film 10F on corrugations C) in step 415, stamp 30 provided in step 110 (as shown in FIG. 7) is contacted to micro-component 20 in step 115, and micro-component 20 micro-transfer is printed in steps 120-135 as discussed with respect to FIG. 7. The process can be repeated with subsequent micro-components 20 by stripping any remaining film 10F and returning to step 405 and recoating film 10F on corrugations C. Film 10F can comprise, for example, silicone.

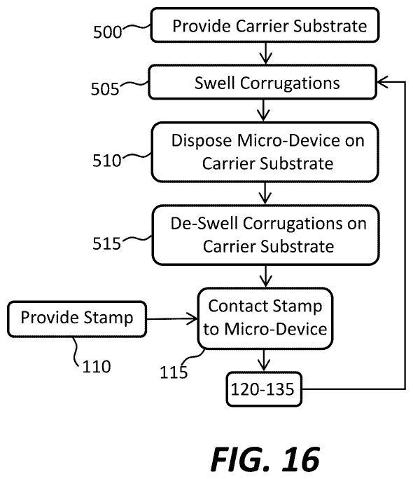

In some embodiments of the present disclosure and as illustrated in FIGS. 15A, 15B, and 16, film 10F is an expandable structure that is processed to change its volume or area in contact with micro-component 20 by swelling or shrinking film 10F. FIG. 15A illustrates micro-components 20 disposed on a planar surface of film 10F over corrugations C in bulk substrate 10B. Film 10F is then dried to remove moisture from film 10F to reduce the volume of film 10F and the area of film 10F in contact with micro-component 20. Film 10F then shrinks over corrugations C, as shown in FIG. 15B. This reduces an area of film 10F in contact with micro-component 20 and reduces the adhesion between film 10F and micro-component 20, so that micro-component 20 can be removed easier from film 10F by contacting micro-component 20 with stamp 30 in a micro-transfer printing process. The process can be repeated by swelling film 10F in step 405, for example by adding moisture to film 10F and disposing successive micro-components 20 on swollen film 10F, as shown in FIG. 15A. Film 10F can comprise, for example, hydrogels. In some embodiments, film 10F comprises PDMS that swells in response to heat and shrinks in response to cooler temperatures.

Thus, according to methods of the present disclosure and as illustrated in FIG. 16, a carrier substrate 10 with a film 10F and corrugations C is provided in step 500, corrugations C swelled or otherwise increased in size or area or maintained at a relatively large size or area in step 505 (e.g., by adding or maintaining moisture in film 10F or by heating film 10F), micro-component 20 is disposed on carrier substrate 10 in contact with corrugations C of film 10F in step 510, film 10F is decreased in size or area (e.g., by drying or baking film 10F or by cooling film 10F) in step 515, stamp 30 provided in step 110 (as shown in FIG. 7) is contacted to micro-component 20 in step 115, and micro-component 20 micro-transfer printed in steps 120-135 as discussed with respect to FIG. 7. The process can be repeated with subsequent micro-components 20 by returning to step 505 without replacing film 10F, but instead repeatedly swelling (by adding moisture, e.g., water or humidity or heating) to film 10F and shrinking (e.g., by drying or by cooling) film 10F to increase and decrease the area of film 10F in contact with micro-component 20 and thereby increasing or decreasing adhesion between film 10F of carrier substrate 10 and micro-component 20 to enable adhesion to carrier substrate 10 and subsequent removal of micro-component 20 from carrier substrate 10.

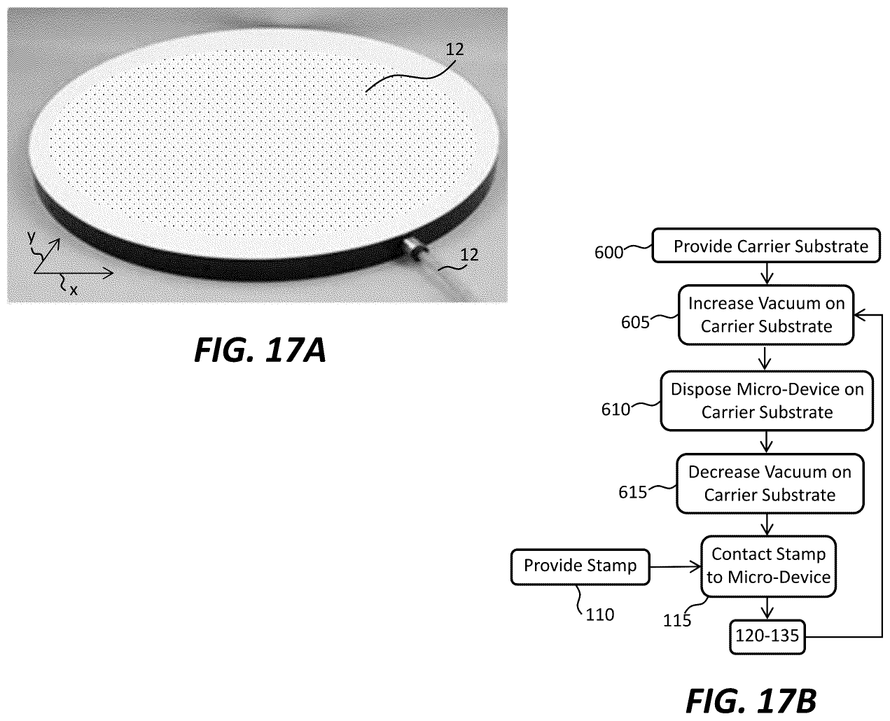

In some embodiments of the present disclosure, carrier substrate 10 comprises holes that are attached to a vacuum 12 (or reduced air pressure 12). The air pressure in vacuum holes 12 is reduced when disposing micro-components 20 on carrier substrate 10 so that micro-components 20 are held in place on carrier substrate 10 by atmospheric air pressure and increased when removing micro-components 20 from carrier substrate 10. FIG. 17A illustrates carrier substrate 10 with vacuum holes 12 and FIG. 17B illustrates a method of use. Note that conventional vacuum plates have relatively large holes relatively far apart for adhering relatively large structures (e.g., wafers). According to embodiments of the present disclosure, micro-components 20 are much smaller, e.g., have sizes or linear dimensions parallel to a major surface of carrier substrate 10 (e.g., in the x and y directions) no greater than fifty, twenty, ten, five, two or one microns, and the holes have diameters that are smaller than micro-components 20 and are spaced apart by a distance less than a linear dimension of micro-components 20, for example have a diameter or spacing that is no greater than one half, one quarter, one tenth, one twentieth, one fiftieth, one hundredth, or one thousandth of a micro-component linear dimension. In some embodiments, carrier substrate 10 is or comprises an aerogel with pores having a diameter no greater than ten, one, one tenth, one hundredth, or one thousandth of a micron.

Thus, according to methods of the present disclosure and as illustrated in FIG. 17B, a carrier substrate 10 with vacuum holes 12 attached to a vacuum source is provided in step 600, the vacuum on vacuum holes 12 is increased or maintained at a relatively high level (e.g., a vacuum or relatively low air pressure is provided to vacuum holes 12) in step 605, micro-component 20 is disposed on carrier substrate 10 in contact with or closely adjacent to vacuum holes 12 in step 610, the vacuum is decreased (e.g., the vacuum is released or a relatively high air pressure such as a local atmospheric air pressure is provided) in step 615, stamp 30 provided in step 110 (as shown in FIG. 7) is contacted to micro-component 20 in step 115, and micro-component 20 micro-transfer printed in steps 120-135 as discussed with respect to FIG. 7. The process can be repeated with subsequent micro-components 20 by returning to step 605.

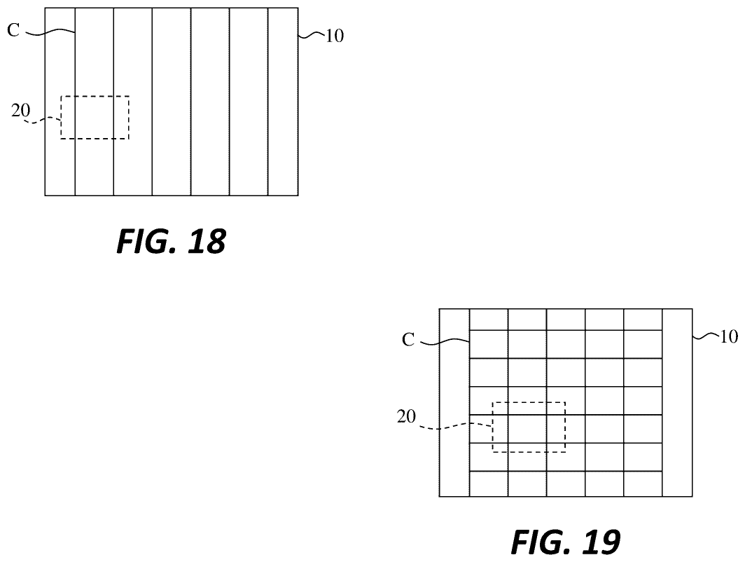

In some embodiments of the present disclosure and as illustrated in FIG. 18, corrugations C extend over carrier substrate 10 in one dimension. As illustrated in FIG. 19, corrugations C extend over carrier substrate 10 in two dimensions.

Micro-components 20 can have a variety of different sizes suitable for micro-transfer printing. For example, micro-components 20 can have at least one of a width from 2 to 5 μm, 5 to 10 μm, 10 to 20 μm, or 20 to 50 μm, a length from 2 to 5 μm, 5 to 10 μm, 10 to 20 μm, or 20 to 50 μm, and a height (thickness) from 2 to 5 μm, 4 to 10 μm, 10 to 20 μm, or 20 to 50 μm. When micro-transfer printed from a source wafer, micro-components 20 can comprise a fractured (e.g., broken) or separated tether.

Micro-components 20 can be micro-devices 20. For example, micro-components 20 can be small integrated circuits. Micro-components 20 can be complete micro-devices 20 or portions thereof. For example, micro-components 20 can be unfinished micro-devices 20 that lack, for example, terminals or electrical connections or other elements that are required or desirable to having micro-devices 20 perform an intended function. Micro-components 20 can be one or more elements that are used to form a micro-device (e.g., when printed to a common substrate and electrically connected together). Micro-devices 20 can be bare, unpackaged die. Micro-devices 20 can be, for example, electronic devices, optoelectronic devices, photonic devices, piezoelectric devices, micro-electromechanical systems (MEMS) devices, sensors, controllers, or measurement devices. Micro-devices 20 can be active or passive devices. In some embodiments, micro-components 20 are light emitters (e.g., organic or inorganic light-emitting diodes (LEDs)).

Micro-components or micro-devices 20 can be any of a wide variety of devices, such as, for example but not limited to, electronic, optical, optoelectronic, mechanical, or piezoelectric devices. Micro-components 20 can be optically emissive or responsive and can be light emitters (such as LEDs), light sensors (such as photodiodes), lasers, or electrical jumpers. Micro-components 20 can be integrated circuits (for example CMOS, bipolar, or mixed circuits). Micro-components 20 can comprise electronically active or passive electronic elements or both. Micro-components 20 can be constructed using photolithographic methods and materials. Micro-components 20 can comprise two or more elements that have been fabricated (e.g., by photolithography) and/or assembled (e.g., by micro-transfer printing) on a substrate. Micro-components 20 can have, for example, at least one of a width, length, and height from 2 μm to 1000 μm (for example 2 to 5 μm, 5 to 10 μm, 10 to 20 μm, 20 to 50 μm, 50 μm to 100 μm, 100 μm to 250 μm, 250 μm to 500 μm, or 500 μm to 1000 μm). Micro-components 20, for example, can have a substrate thickness from 2 μm to 50 μm (for example from 2 to 5 μm, 5 to 10 μm, 10 to 20 μm, or 20 to 50 μm). Micro-components 20 can have a length greater than width, for example having an aspect ratio greater than or equal to 2 (for example greater than or equal to 4, 8, 10, 20, or 50).

Methods of forming micro-transfer printable structures are described, for example, in the paper AMOLED Displays using Transfer-Printed Integrated Circuits (Journal of the Society for Information Display, 2011, DOI #10.1889/JSID19.4.335, 1071-0922/11/1904-0335, pages 335-341) and U.S. Pat. No. 8,889,485. For a discussion of micro-transfer printing techniques see U.S. Pat. Nos. 8,722,458, 7,622,367 and 8,506,867, of which the disclosure of micro-transfer printing techniques (e.g., methods and structures) in each is hereby incorporated by reference. Micro-transfer printing using compound micro-assembly structures and methods can also be used with certain embodiments of the present disclosure, for example, as described in U.S. patent application Ser. No. 14/822,868, filed Aug. 10, 2015, entitled Compound Micro-Assembly Strategies and Devices, from which the description of compound micro-assembly structures and methods is hereby incorporated by reference. A micro-component 20 can be a compound micro-system or portion thereof (e.g., device thereof). Additional details useful in understanding and performing aspects of some embodiments of the present disclosure are described in U.S. Pat. No. 9,520,537, filed Jun. 18, 2015, entitled Micro Assembled LED Displays and Lighting Elements, which is hereby incorporated by reference in its entirety.

Reference is made throughout the present description to examples of printing (e.g., micro-transfer printing) with stamp 30 when describing certain examples of printing micro-components 20. A stamp 30 is an elastomeric transfer device 30. Similar other embodiments are expressly contemplated where a transfer device 30 that is not a stamp 30 is used to similarly print micro-components 20. For example, in some embodiments, a transfer device 30 that is a vacuum-based or electrostatic transfer device 30 can be used to print micro-components 20. A vacuum-based or electrostatic transfer device 30 can comprise a plurality of transfer posts, each transfer post being constructed and arranged to pick up a single micro-component 20 (similarly to stamp posts in stamp 30).

Micro-components 20 can be adhered to transfer device (e.g., stamp) 30, carrier substrate 10, or a target substrate by, for example, van der Waals forces, electrostatic forces, magnetic forces, chemical forces, adhesives, or any combination thereof. In some embodiments, PDMS is used on one or both of a transfer device 30 and a carrier substrate 10 to provide different relative adhesiveness (e.g., using different compositions of the PDMS) and/or different relative adhesion (e.g., using different adhesiveness, different contact areas (e.g., at a same adhesiveness), and/or rate-dependent adhesions). In some embodiments, micro-components 20 are adhered to transfer device 30 with separation-rate-dependent adhesion, for example kinetic control of viscoelastic stamp materials such as can be found in elastomeric transfer devices such as a PDMS stamps 30. Transfer devices 30 can be patterned or unpatterned and can comprise stamp posts. Stamp posts can have a length, a width, or both a length and a width, similar or substantially equal to a length, a width, or both a length and a width of micro-components 20 or not (e.g., where relative adhesion is controlled using, at least in part, relative differences in contact area). In some embodiments, stamp posts can be smaller than micro-components 20 or have a dimension, such as a length and/or a width, substantially equal to or smaller than a length or a width of corrugations. In some embodiments, stamp posts each have a contact surface of substantially identical area.

In exemplary methods, a viscoelastic elastomer (e.g., PDMS) stamp 30 (e.g., comprising a plurality of stamp posts) is constructed and arranged to retrieve and transfer micro-components 30 from their native component source wafer onto non-native substrates (e.g., carrier substrate 10). In exemplary methods, a viscoelastic elastomer (e.g., PDMS) stamp 30 (e.g., comprising a plurality of stamp posts) is constructed and arranged to retrieve and transfer micro-components 30 from carrier substrate 10 to a target substrate. In some embodiments, such stamps 30 mount onto motion-plus-optics machinery (e.g., an opto-mechatronic motion platform) that can precisely control stamp 30 alignment and kinetics with respect to two or more of component source wafers, carrier substrates 10, and target substrates. During printing, the motion platform brings stamp 30 into contact with micro-components 20 (e.g., on a component source wafer or carrier substrate 10), with optical alignment performed before contact. Rapid upward movement of the print-head (or, in some embodiments, downward movement of the source wafer or carrier substrate 10) transfers micro-component(s) 20 to stamp 30 (e.g., stamp posts thereof). The populated stamp 30 then travels to carrier substrate 10 or a target substrate (or vice versa) and one or more micro-components 20 are then aligned to that substrate and printed.

While stamp 30 is referred to as an elastomeric transfer device 30, stamp 30 need not be made entirely of elastomeric material. For example, stamp 30 may use elastomeric material only to provide a contact surface for micro-components 20. In some embodiments, stamp 30 includes elastomeric stamp posts. In some embodiments, stamp 30 includes a transparent rigid support (e.g., a glass support), for example to enable optical alignment of stamp 30 to micro-component(s) 20 during printing.

Various embodiments were described above as printing a micro-component 20. Corresponding embodiments that print multiple micro-components 20 are expressly contemplated (e.g., as demonstrated by the Figures). For example, a single print operation may pick-up and print at least 2, at least 5, at least 10, at least 100, at least 1,000, at least 10,000, or at least 100,000 micro-components 20.

As is understood by those skilled in the art, the terms “over” and “under” are relative terms and can be interchanged in reference to different orientations of the layers, elements, and substrates included in the present disclosure. For example, a first layer on a second layer, in some implementations means a first layer directly on and in contact with a second layer. In other implementations, a first layer on a second layer includes a first layer and a second layer with another layer therebetween.

Having described certain implementations of embodiments, it will now become apparent to one of skill in the art that other implementations incorporating the concepts of the disclosure may be used. Therefore, the disclosure should not be limited to certain implementations, but rather should be limited only by the spirit and scope of the following claims.

Throughout the description, where apparatus and systems are described as having, including, or comprising specific components, or where processes and methods are described as having, including, or comprising specific steps, it is contemplated that, additionally, there are apparatus, and systems of the disclosed technology that consist essentially of, or consist of, the recited components, and that there are processes and methods according to the disclosed technology that consist essentially of, or consist of, the recited processing steps.

It should be understood that the order of steps or order for performing certain action is immaterial so long as the disclosed technology remains operable. Moreover, two or more steps or actions in some circumstances can be conducted simultaneously. The disclosure has been described in detail with particular reference to certain embodiments thereof, but it will be understood that variations and modifications can be effected within the spirit and scope of the claimed invention.

### PARTS LIST

C corrugation
H height
10 carrier substrate
10B bulk substrate/bulk layer
10C corrugated surface
10F film
12 vacuum/vacuum supply/vacuum holes
20 micro-component/micro-device
20B device bottom/bottom side/bottom surface
30 stamp/transfer device
30A first stamp/weak-adhesion stamp/narrow-post stamp
30B second stamp/strong-adhesion stamp/wide-post stamp
30P stamp post
90 micro-component substrate structure
100 provide carrier substrate step
105 dispose micro-component on carrier substrate step
110 provide stamp step
115 contact stamp to micro-component step
120 remove micro-component from carrier substrate with stamp step
125 provide target substrate step
130 print micro-component onto target substrate step
135 remove stamp step
200 provide carrier substrate with first adhesion step
205 dispose micro-component on carrier substrate step
210 provide stamp with second adhesion step
215 provide stamp with third adhesion step
220 dispose micro-component on carrier substrate step
300 provide carrier substrate step
305 set carrier substrate to first temperature step
310 dispose micro-component on carrier substrate step
315 set carrier substrate to second temperature step
400 provide carrier substrate step
405 coat carrier substrate step
410 dispose micro-component on carrier substrate step
415 etch corrugations on carrier substrate step
500 provide carrier substrate step
505 swell corrugations step
510 dispose micro-component on carrier substrate step
515 de-swell corrugations on carrier substrate step
600 provide carrier substrate step
605 increase vacuum on carrier substrate step
610 dispose micro-component on carrier substrate step
615 decrease vacuum on carrier substrate step

1. A micro-component substrate structure, comprising:
a carrier substrate having a corrugated surface; and
a micro-component having a bottom surface disposed on the corrugated surface.

2. The micro-component substrate structure of claim 1, wherein the corrugated surface comprises an array of rounded, pyramidal, cylindrical, rectangular, or tetrahedral corrugations.

3. The micro-component substrate structure of claim 2, wherein no more than 25% of an outermost surface of each of one or more of the corrugations is in contact with the micro-component.

4. The micro-component substrate structure of claim 2, wherein a plurality of the corrugations is in contact with the micro-component.

5. The micro-component substrate structure of claim 1, wherein (i) the carrier substrate comprises a bulk layer coated with a film, (ii) the bulk layer comprises a bulk material, (iii) the film comprises a film material different from the bulk material, and (iv) the film comprises the corrugated surface.

6. The micro-component substrate structure of claim 5, wherein the film comprises corrugations defining the corrugated surface.

7. The micro-component substrate structure of claim 5, wherein the bulk layer comprises corrugations and the film is disposed on the corrugations.

8. The micro-component of claim 7, wherein the bulk layer is a rigid layer.

9. The micro-component of claim 7, wherein the corrugations are made of a rigid material.

10. The micro-component substrate structure of claim 5, wherein (i) the film is or comprises PDMS, (ii) the bulk material is silicon, or both (i) and (ii).

11. The micro-component substrate structure of claim 5, wherein the film has a thickness of no greater than ten microns.

12. The micro-component substrate structure of claim 1, wherein the corrugated surface has corrugations having a height of no greater than one hundred microns.

13. The micro-component substrate structure of claim 1, wherein a plurality of micro-components is in contact with the corrugated surface.

14. The micro-component substrate structure of claim 1, wherein a surface material of the corrugated surface has been processed to reduce adhesion between the micro-component and the corrugated surface.

15. A method of transfer printing a micro-component, the method comprising:
providing a micro-component substrate structure according to claim 1;
providing a transfer device;
contacting the transfer device to the micro-component; and
removing the micro-component from the corrugated surface with the stamp.

16. The method of claim 15, wherein the transfer device is a stamp and an area of the micro-component in direct contact with the corrugated surface is less than an area of the micro-component in contact with the stamp when removing the micro-component from the corrugated surface with the stamp.

17. The method of claim 15, wherein the micro-component is a first micro-component disposed on a first region of the corrugated surface and the method comprises disposing a second micro-component in direct contact with the carrier substrate in a second region at least partially overlapping the first region after the first micro-component is removed from the carrier substrate.

18. A method of transfer printing a micro-component, the method comprising:
providing a carrier substrate;
providing a micro-component adhered to the carrier substrate with a carrier-substrate adhesion;
providing a transfer device;
contacting the stamp to the micro-component such that a transfer-device adhesion to the micro-component is greater than the carrier-substrate adhesion to the micro-component; and
removing the micro-component from the carrier substrate with the transfer device, wherein
(i) the carrier substrate has a corrugated surface, and the corrugated surface provides the carrier-substrate adhesion to the micro-component,
(ii) a material of the transfer device in contact with the micro-component is different from a material of the carrier substrate in contact with the micro-component, or
(iii) both (i) and (ii).

19. The method of claim 18, wherein:
the carrier substrate comprises a layer of PDMS that provides the carrier-substrate adhesion to the micro-component, the layer of PDMS of the carrier substrate having a substrate composition, and
the transfer device comprises a layer of PDMS that provides the transfer device adhesion to the micro-component, the layer of PDMS of the transfer device having a stamp composition different from the substrate composition.

20. The method of claim 19, wherein the layer of PDMS on the transfer device is more adhesive than the layer of PDMS on the carrier substrate over an equivalent area to an equivalent material.

21.-47. (canceled)
